(19) United States
(12) Patent Application Publication
(10) Pub. No.: US 2011/0174527 A1
(43) Pub. Date: Jul. 21, 2011

(54) ELEMENT MOUNTING BOARD, SEMICONDUCTOR MODULE, SEMICONDUCTOR DEVICE, METHOD FOR FABRICATING THE ELEMENT MOUNTING BOARD, AND METHOD FOR FABRICATING SEMICONDUCTOR DEVICE

(76) Inventors: Masayuki Nagamatsu, Gifu (JP); Ryosuke Usui, Aichi (JP); Kiyoshi Shibata, Gifu (JP)

(21) Appl. No.: 13/002,189

(22) PCT Filed: Jun. 30, 2009
(86) PCT No.: PCT/JP2009/003036

§ 371 Date: Mar. 25, 2011

(30) Foreign Application Priority Data
Jun. 30, 2008 (JP) 2008-171830
Sep. 29, 2008 (JP) 2008-251382

(51) Int. Cl. H05K 1/11; H01L 23/488; H05K 3/34; H01L 21/58; H05K 3/10

(52) U.S. Cl. 174/261; 257/779; 257/777; 438/107; 29/849; 257/E23.023; 257/E21.511

(57) ABSTRACT

A semiconductor device is of a PoP structure such that first electrode portions provided in a first semiconductor module and second electrode portions provided in a second semiconductor module are joined together by solder balls. The first electrode has a first conductor having the same thickness as that of a wiring layer provided in an insulating layer, a second conductor formed on the first conductor, a gold plating layer provided on the second conductor.

### BACKGROUND OF THE INVENTION

1. Technical Field

The present invention relates to an element mounting board used to mount semiconductor elements thereon. More particularly, the present invention relates to a semiconductor device having a package-on-package structure and an element mounting board on which the semiconductor device can be mounted using a flip-chip mounting method.

2. Background Technology

In recent years, with miniaturization and higher performance in electronic devices, demand has been ever greater for further miniaturization and higher density of semiconductor devices used in the electronic devices. In response to such demand, widely known is a semiconductor module stacking technique such as a 3D packaging technique which is called a package-on-package (PoP) where two or more packages are installed on top of one another.

For example, one mode of fabrication in a 3D package is disclosed in Patent Document 1. Patent Document 1 discloses a package structure where solder is supplied in the position of through-hole wiring. Referring to FIG. 12 of Patent Document 1, one finds that solder is supplied onto the through-hole wiring only. Solder balls are placed on this solder and a similar package, where the solder is supplied and the solder balls are placed thereon, is stacked.

Also, a semiconductor device can be made smaller and thinner by reducing the packaging area occupied by the semiconductor element on an element mounting board, for instance. A known method for reducing the packaging area of the semiconductor element on the element mounting board is as follows. That is, a flip-chip mounting method is known where a solder bump is formed on an external connection electrode of the semiconductor element and then the solder bump and an electrode pad on the element mounting board is soldered together.

### PRIOR ART DOCUMENT

### Patent Document

[Patent Document 1] Japanese Unexamined Patent Application Publication No. Hei04-280695.

### DISCLOSURE OF THE INVENTION

### Problems to be Solved by the Invention

In the conventional PoP structure, the height of the solder ball used for the mounting of the top package needs to be high so that the bottom face of the topside package does not interfere with the top surface of the downside package. Also, in the semiconductor device where a semiconductor element is mounted on the element mounting board by flip-chip mounting, the height of the solder ball used for the flip-chip mounting needs to be set high in order to allow a space between the semiconductor element and the element mounting board. An increase in the height of the solder ball entails an increase in the diameter of the solder ball. Accordingly, the area occupied by the solder ball itself increases and therefore the area of the electrode pad used to mount the solder balls increases. This presents an impediment to the attempts at further miniaturization of the semiconductor devices.

The present invention has been made in view of these problems, and a purpose thereof is to provide a technology that reduces the area required by the solder balls and the electrode pads for a package and the mounting of a semiconductor element so as to realize further miniaturization and higher density. Another purpose thereof is to provide a technology by which to improve the connection reliability between the element mounting board and the semiconductor elements.

### Means for Solving the Problems

One embodiment of the present invention relates to an element mounting board. The element mounting board is used to mount a semiconductor element thereon, and the element mounting board comprises: a substrate; a wiring layer formed on one main surface of the substrate; an electrode portion provided on the one main surface of the substrate, the electrode portion being thicker than the thickness of the wiring layer, and the electrode portion being used for solder bonding,

Another embodiment of the present invention relates to a semiconductor module. The semiconductor module comprises: the above-described element mounting board; a semiconductor element mounted at the other main surface side of the substrate; and a sealing resin for sealing the semiconductor element.

Still another embodiment of the present invention relates to a semiconductor device. The semiconductor device comprises: (1) a first semiconductor module including: (i) a substrate; (ii) a first semiconductor element mounted at one main surface side of the substrate; (iii) a sealing resin for sealing the first semiconductor element; (iv) a wiring layer formed on one main surface of the substrate; and (v) a first electrode portion provided on the main surface of the substrate, the first electrode portion having an upper surface, used for solder bonding, which is positioned above an upper surface of the wiring layer; (2) a second semiconductor module, mounted above the sealing resin, having a second electrode portion on a lower surface thereof, wherein a second semiconductor element is packaged in the second semiconductor module; and (3) a solder member for connecting the first electrode portion to the second electrode portion.

Still another embodiment of the present invention relates to a semiconductor device. The semiconductor device comprises: (1) a first semiconductor module including: (i) a substrate; (ii) a first semiconductor element mounted at one main surface side of the substrate; (iii) a sealing resin for sealing the first semiconductor element; (iv) a first wiring layer formed on one main surface of the substrate; and (v) a first electrode portion provided on the main surface of the substrate, the first electrode portion having an upper surface used for solder bonding; (2) a second semiconductor module, mounted above the sealing resin, having a second electrode portion and a second wiring layer on a lower surface thereof; and (3) a solder member for connecting the first electrode portion to the second electrode portion, wherein the thickness of the second electrode portion is greater than that of the second wiring layer.

Still another embodiment of the present invention relates to a method for fabricating an element mounting board. The method for fabricating an element mounting board comprises: a process of patterning a wiring layer on one main surface of a substrate; a process of forming a first insulating layer having an opening in which an electrode region is exposed, the electrode region being designed to bond a solder member used to mount a package; and a process of filling a conductive material into the opening.

Still another embodiment of the present invention relates to a method for fabricating a semiconductor device. The method for fabricating a semiconductor device comprises: a process of preparing a first semiconductor module including a first substrate and a first semiconductor element mounted on the first substrate, wherein the first substrate is such that a wiring layer and a first electrode portion, whose thickness is greater than that of the wiring layer, used for solder bonding are formed in a semiconductor element mounting surface; a process of preparing a second semiconductor module including a second substrate and a second semiconductor element mounted on the second substrate, wherein the second substrate is such that a second electrode portion used for solder bonding is formed in an opposite side of the semiconductor element mounting surface; and a process of joining together the first semiconductor module and the second semiconductor module by placing the second semiconductor module on top of the first semiconductor module.

Still another embodiment of the present invention relates to a method for fabricating a semiconductor device. The method for fabricating a semiconductor device comprises: a process of preparing a first semiconductor module including a first substrate and a first semiconductor element mounted on the first substrate, wherein the first substrate is such that a first electrode portion used for the solder bonding is formed on a semiconductor element mounting surface; a process of preparing a second semiconductor module including a second substrate and a second semiconductor element mounted on the second substrate, wherein the second substrate is such that a wiring layer and a second electrode portion, whose thickness is greater than that of the wiring layer, used for solder bonding are formed in an opposite side of the semiconductor element mounting surface; and a process of joining together the first semiconductor module and the second semiconductor module by placing the second semiconductor module on top of the first semiconductor module.

Still another embodiment of the present invention relates to an element mounting board. The element mounting board comprises: a substrate; a wiring layer, formed on one main surface of the substrate, having an electrode forming region; an insulating layer, provided on a periphery of the electrode forming region, having an opening in which the electrode forming region is exposed; and an electrode electrically connected to the electrode forming region, the electrode having an embedded portion embedded into the opening of the insulating layer and a protrusion protruding above an upper surface of a periphery of the opening of the insulating layer, wherein an peripheral edge of the protrusion lies external to an peripheral edge of the embedded portion, as viewed from above the electrode. By employing this embodiment, the connection reliability between the element mounting board and the semiconductor element can be improved.

In the above-described embodiment, a periphery of a flat part in an upper surface of the protrusion may lie external to the peripheral edge of the embedded portion, as viewed from above the electrode.

In the above-described embodiment, the insulating layer serves as a first insulating layer and the opening serves as a first opening; the element mounting board may further comprise a second insulating layer, provided on a periphery of the first opening on the first insulating layer, the second insulating layer having a second opening in which the electrode forming region is exposed; and the electrode may be such that the embedded portion is embedded into the first opening and the second opening, the protrusion protrudes above an upper surface of a periphery of the second opening of the second insulating layer, and the peripheral edge of the protrusion lies external to that of the embedded portion, as viewed from above the electrode.

In the above-described embodiment, a periphery of a flat part in an upper surface of the protrusion may lie external to the peripheral edge of the embedded portion, as viewed from above the electrode.

In the above-described embodiment, the periphery of the second opening may lie external to that of the first opening, as viewed from above the second insulating layer.

Still another embodiment of the present invention relates to a semiconductor module. The semiconductor module comprises: an element mounting board according to any one of the above-described embodiments; and a semiconductor element provided with an element electrode disposed counter to the electrode, wherein the electrode and the element electrode are electrically connected to each other.

Still another embodiment of the present invention relates to a portable device. The portable device mounts a semiconductor device according to any one of any one of the above described embodiments or a semiconductor module according to any one of the above described embodiments.

Still another embodiment of the present invention relates to a method for fabricating an element mounting board. The method for fabricating an element mounting board comprises: a process of patterning a wiring layer, having an electrode forming region, on one main surface of a substrate; a process of forming an insulating layer having an opening in which the electrode region is exposed; and a process of completely filling the opening with a conductive material, then having the conductive material protrude above an upper surface of a periphery of the opening in the insulating layer, and extending an peripheral edge of the conductive material to a position external to an peripheral edge of the opening, as viewed from above the insulating layer.

In the above-described embodiment, the insulating layer serves as a first insulating layer and the opening serves as a first opening, the method may further comprise a process of forming a second insulating layer, provided on a periphery of the first opening on the first insulating layer, the second insulating layer having a second opening in which the electrode forming region is exposed; in the process of filling the conductive material, the first insulating layer and the second insulating layer may be completely filled with the conductive material, then the conductive material may be made to protrude above an upper surface of a periphery of the second opening in the second insulating layer, and an peripheral edge of the conductive material may be extended to a position external to an peripheral edge of the second opening, as viewed from above the second insulating layer.

### EFFECT OF THE INVENTION

The present invention reduces the area required by the solder balls and the electrode pads for a package and the mounting of a semiconductor element, thereby attaining further miniaturization and higher density of the semiconductor device.

### BRIEF DESCRIPTION OF THE DRAWINGS

FIG. 1 is a schematic cross-sectional view showing a structure of a semiconductor device according to a first embodiment;

FIG. 2 is a partially enlarged view showing a structure of a first electrode portion and its periphery thereof in a semiconductor device according to a first embodiment;

FIGS. 3A to 3C are cross-sectional views showing a process in a method for fabricating a semiconductor device according to a first embodiment;

FIGS. 4A to 4C are cross-sectional views showing a process in a method for fabricating a semiconductor device according to a first embodiment;

FIGS. 5A to 5D are cross-sectional views showing a process in a method for fabricating a semiconductor device according to a first embodiment;

FIGS. 6A to 6C are cross-sectional views showing a process in a method for fabricating a semiconductor device according to a first embodiment;

FIG. 7 is a schematic cross-sectional view showing a structure of a semiconductor device according to a second embodiment;

FIG. 8 is a schematic cross-sectional view showing a structure of a semiconductor device according to a third embodiment;

FIG. 9 is a schematic cross-sectional view showing a structure of a semiconductor device according to a fourth embodiment;

FIG. 10 is a schematic cross-sectional view showing a structure of a semiconductor device according to a fifth embodiment;

FIG. 11 is a schematic cross-sectional view showing a structure of a semiconductor device according to a sixth embodiment;

FIG. 12 is a schematic cross-sectional view showing a structure of a semiconductor device according to a seventh embodiment;

FIG. 13 is a schematic cross-sectional view showing a structure of a semiconductor device according to an eighth embodiment;

FIG. 14 is a schematic cross-sectional view showing a structure of a semiconductor device according to a ninth embodiment;

FIG. 15 is a schematic cross-sectional view showing a structure of a semiconductor device according to a tenth embodiment;

FIG. 16 is a schematic cross-sectional view showing a structure of a semiconductor device according to an eleventh embodiment;

FIG. 17 is a schematic cross-sectional view showing a structure of an element mounting board and a semiconductor module according to a twelfth embodiment;

FIG. 18 is a partially enlarged view showing a structure of an electrode and its periphery thereof in a semiconductor module;

FIG. 19 is a partial plan view showing a structure of an element mounting board;

FIGS. 20A and 20B are partial cross-sectional views of an element mounting board;

FIGS. 21A to 21D are cross-sectional views showing a process in a method for fabricating a semiconductor module;

FIGS. 22A to 22D are cross-sectional views showing a process in a method for fabricating a semiconductor module;

FIGS. 23A to 23C are cross-sectional views showing a process in a method for fabricating a semiconductor module;

FIG. 24 is an SEM photographic image of an electrode of an element mounting board and its surrounding area;

FIG. 25 is a schematic cross-sectional view showing a structure of an element mounting board and a semiconductor module according to a thirteenth embodiment;

FIG. 26 is a partially enlarged view showing a structure of an electrode and its periphery thereof in a semiconductor module;

FIGS. 27A to 27D are cross-sectional views showing a process in a method for fabricating a semiconductor module;

FIGS. 28A to 28C are cross-sectional views showing a process in a method for fabricating a semiconductor module;

FIG. 29 illustrates a structure of a mobile phone according to a fourteenth embodiment;

FIG. 30 is a partial cross-sectional view of a mobile phone; and

FIG. 31 is a partial cross-sectional view of a mobile phone.

### BEST MODE FOR CARRYING OUT THE INVENTION

Hereinbelow, the embodiments will be described with reference to the accompanying drawings. Note that in all of the Figures the same reference numerals are given to the same components and the repeated description thereof is omitted as appropriate.

### First Embodiment

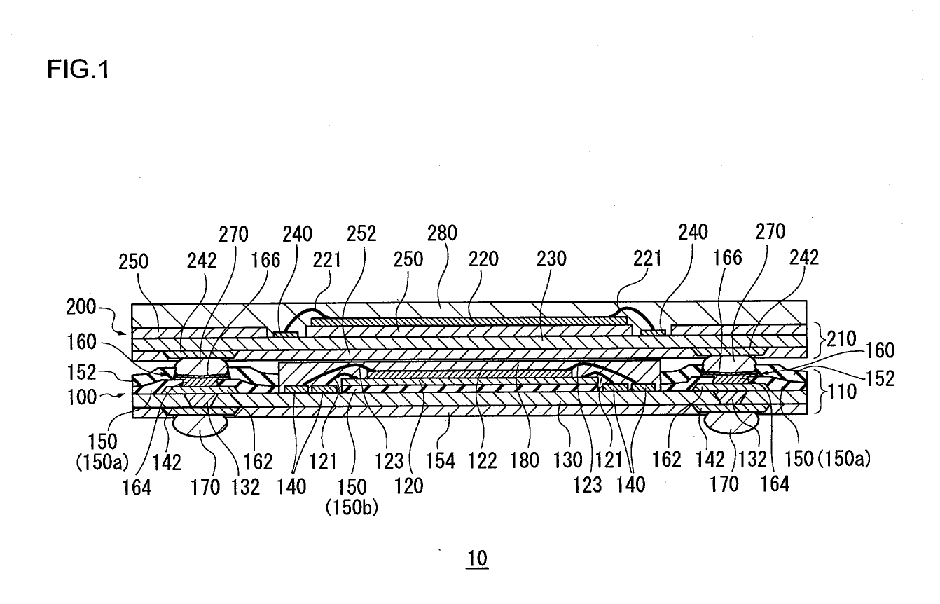

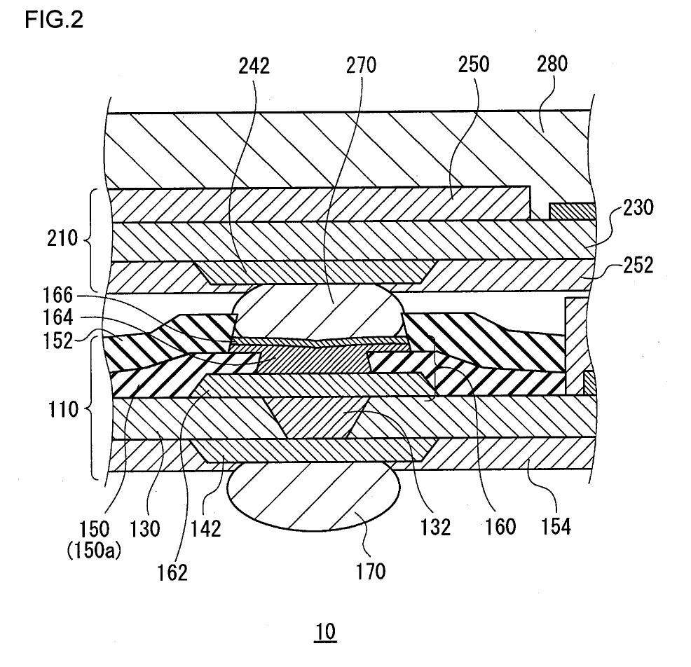

FIG. 1 is a schematic cross-sectional view showing a structure of a semiconductor device 10 according to a first embodiment of the present invention. FIG. 2 is a partially enlarged view showing a structure of a first electrode portion 160 in the semiconductor device 10 and the periphery of the first electrode portion 160. The semiconductor device 10 has a package-on-package (PoP) structure wherein the semiconductor device 10 includes a first semiconductor module 100 and a second semiconductor module 200 stacked on top of the first semiconductor module 100.

The first semiconductor module 100 has a structure where two semiconductor elements 120 and 122 are stacked on an element mounting board 110.

The element mounting board 110 includes an insulating resin layer 130 as a base material, a wiring layer 140 formed on one of main surfaces of the insulating resin layer 130, a third electrode portion 142 formed on the other of main surfaces of the insulating resin layer 130, a first insulating layer 150, and a second insulating layer 152. Here, both the first insulating layer 150 and the second insulating layer 152 are formed on the one main surface of the insulating resin layer 130.

The insulating resin layer 130 may be formed of a thermosetting resin such as a melamine derivative (e.g., BT resin), liquid-crystal polymer, epoxy resin, PPE resin, polyimide resin, fluorine resin, phenol resin or polyamide bismaleimide, or the like.

The wiring layer 140 of a predetermined pattern is provided on the one main surface of the insulating resin layer 130 (i.e., on a semiconductor element mounting surface in the present embodiment). The first electrode portion 160 used to joint a package mounting solder is provided on one main surface of the insulating resin layer 130. The detail of the first electrode portion 160 will be described later. The third electrode portion 142 of a predetermined pattern is provided on the other main surface of the insulating resin layer 130. A material that forms the wiring layer 140 and the third electrode portion 142 may be copper, for instance. The thickness of the wiring layer 140 and the thickness of the third electrode portion 142 may each be 20 μm, for instance. Though not particularly shown in the Figures, another wiring layer which belongs to the same layer to which the third electrode portion 142 belongs is provided on the other main surface thereof, and this another wiring layer has the same height as that of the third electrode portion 142.

Via conductors 132, which penetrate the insulating resin layer 130, are provided in predetermined positions of the insulating resin layer 130. The via conductor 132 is formed by a copper plating, for instance. The first electrode portion 160 and the third electrode portion 142 are electrically connected to each other through the via conductor 142.

The first insulating layer 150 is provided on one main surface of the insulating resin layer 130. The first insulating layer 150 is divided into a first insulating layer 150a disposed on the periphery of the first electrode portion 160 and a first insulating layer 150b disposed in a semiconductor element mounting region.

The first insulating layer 150a covers a periphery of the first electrode portion 160 and an upper-surface peripheral edge part of the first electrode portion 160. In other words, an opening is provided in the first insulating layer 150a in such a manner that a central region of the first electrode portion 160 is exposed.

The second insulating layer 152 is stacked on top of the first insulating layer 150a so that a top surface of the first insulating layer 150a on a peripheral edge of the opening can be exposed.

The first insulating layer 150 and the second insulating layer 152 are formed of photo solder resists, for instance. The thickness of the first insulating layer 150a is 20 μm to 30 μm, for instance. Also, the thickness of the second insulating layer 152 is 50 μm, for instance.

The first electrode portion 160 includes a first conductor 162, a second conductor 164, and a gold plating layer 166.

The first conductor 162 belongs to the same layer to which the wiring layer 140 belongs, and is formed on the one main surface of the insulating resin layer 130. Further, the thickness of the first conductor 162 is equivalent to that of the wiring layer 140 (e.g., 20 μm). The diameter of the first conductor 162 is 350 μm, for instance.

The second conductor 164 is filled into a space formed by a top face of the first conductor 162, a side wall of the first insulating layer 150a and a side wall of the second insulating layer 152. In other words, the second conductor 164 is completely filled into an opening provided in the first insulating layer 150a and is partially filled into an opening provided in the second insulating layer 152. The diameter of the opening provided in the second insulating layer 152 is greater than that of the opening provided in the first insulating layer 150a. Thus, the diameter of the second conductor 164 is such that the diameter of the second conductor 164 in a region provided in the opening of the second insulating layer 152 is greater than that in a region provided in the opening of the first insulating layer 150a. In other words, the cross section of the second conductor 164 is of a T-shape or mushroom shape. The thickness of the second conductor 164 is 40 μm, for instance.

Also, the gold plating layer 166 such as a Ni/Au layer is formed on a top face of the second conductor 164. Provision of the gold plating layer 166 suppresses the oxidation of the second conductor 164. If the Ni/Au layer is to be formed as the gold plating layer 166, the thickness of Ni layer will be 1 μm to 15 μm, for instance, and the thickness of Au layer will be 0.03 μm to 1 μm, for instance.

A third insulating layer 154 is provided on the other main surface of the insulating resin layer 130. The third insulating layer 154 has openings in which solder balls 170 are placed on the third electrode portions 142. The solder ball 170 is connected to the third electrode portion 142 within the opening provided in the third insulating layer 154.

The two semiconductor elements 120 and 122 are mounted on the above-described element mounting board 110. More specifically, the first semiconductor element 120 is mounted on top of the first insulating layer 150b. Further, the semiconductor element 122 is mounted on top of the semiconductor element 120. An element electrode (not shown) provided on the semiconductor element 120 and a predetermined region of the wiring layer 140 are wire-bonded to each other using a gold wire 121. Also, an element electrode (not shown) provided on the semiconductor element 122 and a predetermined region of the wiring layer 140 are wire-bonded to each other using a gold wire 123. An example of the semiconductor elements 120 and 122 is a semiconductor chip such as an integrated circuit (IC) or a large-scale integrated circuit (LSI).

A sealing resin layer 180 seals the semiconductor elements 120 and 122 and the wiring layer 140 connected thereto. The sealing resin layer 180 is formed of epoxy resin, for instance, by using a transfer mold method.

The second semiconductor module 200 is structured such that a semiconductor element 220 is mounted on an element mounting board 210.

The element mounting board 210 includes an insulating resin layer 230 as a base material, a wiring layer 240 formed on one of main surfaces of the insulating resin layer 230, a second electrode portion 242 formed on the other of main surfaces of the insulating resin layer 230, a fourth insulating layer 250 formed on the one main surface of the insulating resin layer 230, and a fifth insulating layer 252 formed on the other main surface of the insulating resin layer 230.

The insulating resin layer 230 may be formed of a thermosetting resin such as a melamine derivative (e.g., BT resin), liquid-crystal polymer, epoxy resin, PPE resin, polyimide resin, fluorine resin, phenol resin or polyamide bismaleimide, or the like.

The wiring layer 240 of a predetermined pattern is provided on the one main surface (semiconductor element mounting surface) of the insulating resin layer 230. A gold plating layer may be formed on top of the wiring layer 240. The second electrode portion 242 is provided on the other main surface of the insulating resin layer 230. A material that forms the wiring layer 240 and the second electrode portion 242 may be copper, for instance. The wiring layer 240 and the second electrode portion 242 are electrically coupled to each other by a via conductor (not shown) that penetrates the insulating resin layer 230 in a predetermined position. Though not particularly shown in the Figures, another wiring layer which belongs to the same layer to which the second electrode portion 242 belongs is provided on the other main surface of the insulating resin layer 230, and this another wiring layer has the same height as that of the second electrode portion 242.

The fourth insulating layer 250 formed of a photo solder resist or the like is provided on the one main surface of the insulating resin layer 230. Also, the fifth insulating layer 252 formed of a photo solder resist or the like is provided on the other main surface of the insulating resin layer 230. The fifth insulating layer 252 has openings in which solder balls 270 are placed on the second electrode portions 242. The solder ball 270 is connected to the second electrode portion 242 within the opening provided in the fifth insulating layer 252.

The semiconductor element 220 is mounted on the above-described element mounting board 210. More specifically, the semiconductor element 220 is mounted on top of the fourth insulating layer 250. An element electrode (not shown) provided on the semiconductor element 220 and a predetermined region of the wiring layer 240 are wire-bonded to each other using a gold wire 221. An example of the semiconductor element 220 is a semiconductor chip such as an integrated circuit (IC) or a large-scale integrated circuit (LSI).

A sealing resin layer 280 seals the semiconductor device 220 and the wiring layer 240 connected thereto. The sealing resin layer 280 is formed of epoxy resin, for instance, by using the transfer mold method.

A PoP structure, where the second semiconductor module 200 is mounted above the first semiconductor module 100 (above the sealing resin layer 180) is achieved in such a manner that the first electrode portions 160 of the first semiconductor module 100 and the second electrode portions 242 of the second semiconductor module 200 are joined to the solder balls 270.

(Method for Fabricating a Semiconductor Device)

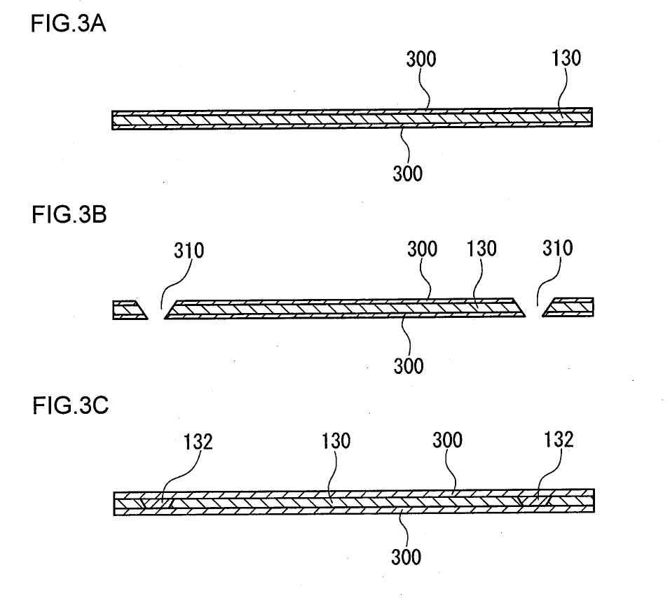

A method for manufacturing a semiconductor device according to the first embodiment is described with reference to FIG. 3A to FIG. 6C. As shown in FIG. 3A, an insulating resin layer 130 to which copper foils 300 are attached to the both main surfaces thereof is first prepared.

Then, as shown in FIG. 3B, predetermined regions of the insulating resin layer 130 and the copper coil 300 are drilled by a drilling process, such as a drill or laser process, so as to form via holes 310 there.

Then, as shown in FIG. 3C, the via holes 310 are filled with copper by using an electroless plating method and an electrolytic plating method, thereby forming via conductors 132. At the same time, the copper foils 300 provided on the both main surfaces thereof are thickened.

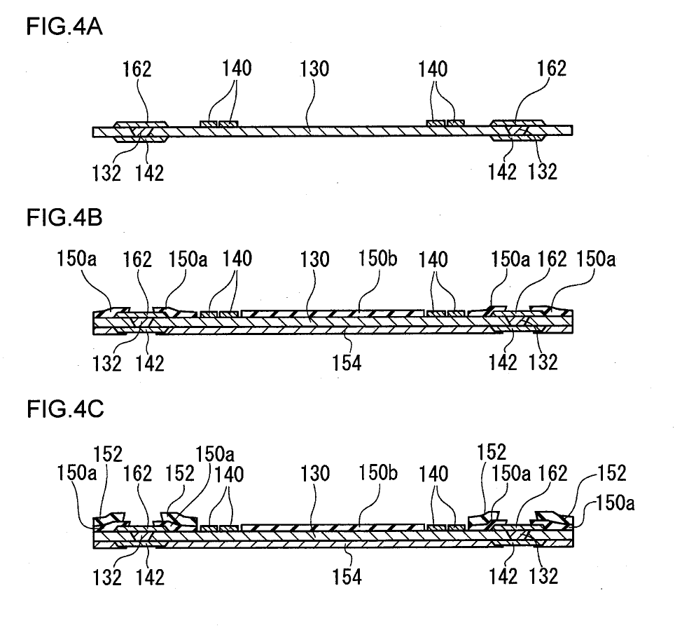

As shown in FIG. 4A, a wiring layer 140 and a first conductor 162 of predetermined patterns and a third electrode portion 142 of a predetermined pattern are formed on one main surface of the insulating resin layer 130 and the other main surface thereof (opposite to the semiconductor element mounting surface), respectively, using known photolithography method and etching method.

Then, as shown in FIG. 4B, using known photolithography method and etching method, a first insulating layer 150a, in which an opening is so provided that a central region of the first conductor 162 is exposed, and a first insulating layer 150b, in which an opening is so provided that the wiring layer 140 is exposed, are formed on the main surface of the insulating resin layer 130. Similarly, a third insulating resin layer 154, in which an opening is so provided that a central region of the third electrode portion 142 is exposed, is formed on the other main surface thereof. Since the wiring layer 140 and the first conductor 162 are both formed of the copper foil 300 as shown in FIG. 3C, the height of the wiring layer 140 is the same as that of the first conductor 162.

Then, as shown in FIG. 4C, a second insulating layer 152 having an opening such that an upper surface of the first insulating layer 150a is exposed in a circumferential edge of the opening is formed, using known photolithography method and etching method. In other words, the size of the opening provided in the second insulating layer 152 is made larger than that of the opening provided in the first insulating layer 150a.

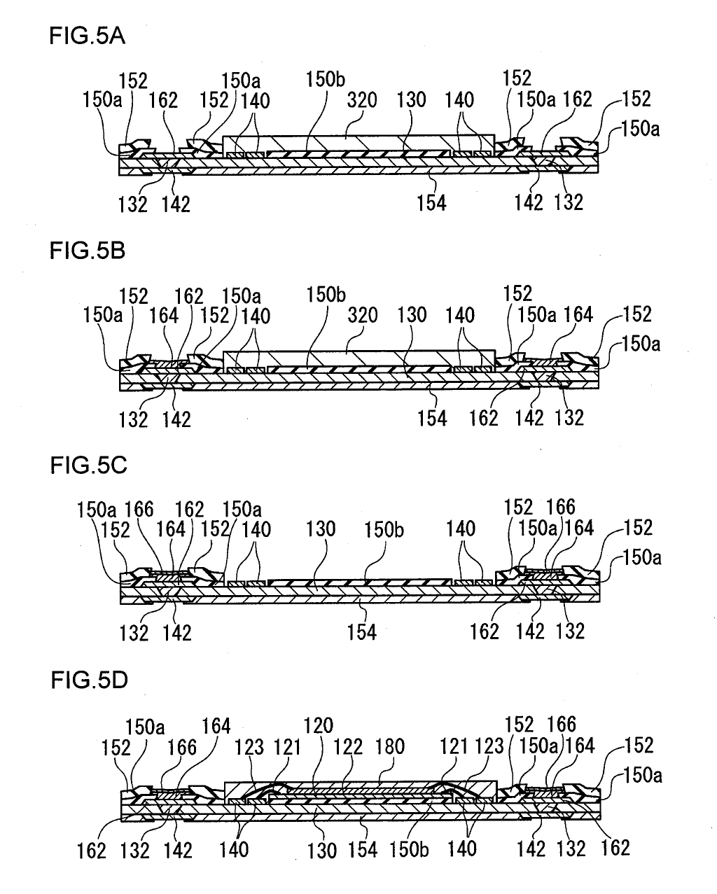

Then, as shown in FIG. 5A, a resist 320 covering the wiring layer 140 is formed, using known photolithography method and etching method.

Then, as shown in FIG. 5B, openings provided in the first insulating layer 150a and the second insulting layer 152 are filled with copper from above the first conductor 162, by an electrolytic plating. In this plating process, copper is first gradually filled into the opening provided in the first insulating layer 150a and then the opening provided in the first insulating layer 150a is completely filled with copper. Furthermore, the copper starts to spread over a top surface of the first insulating layer 150a and then blocked by the second insulating layer 152. Then the copper is gradually built up by the plating and is filled into the opening provided in the second insulating layer 152 up to a predetermined height. This process results in the formation of the second conductor 164 on top of the first conductor 162. The cross section or profile of the second conductor 164 is of a T-shape or mushroom shape.

Then, as shown in FIG. 5C, after the removal of the resist 320 (see FIG. 5B), a gold plating layer 166 comprised of an Ni/Au layer is formed on the second conductor 164 by a gold plating. Through the above-described processes, the element mounting board 110 according to the first embodiment is formed. When the gold plating layer 166 is formed on the second conductor 164, a gold plating layer may also similarly be formed on a land area of the wiring layer 140.

Then, as illustrated in FIG. 5D, the semiconductor element 120 is mounted on the first insulating layer 150b, and the semiconductor element 122 is mounted on top of the semiconductor element 120. An element electrode (not shown) provided in an upper-surface peripheral edge part of the semiconductor element 120 is connected to an electrode region of the wiring layer 140 by a gold wire 121, using a wire bonding method. Similarly, an element electrode (not shown) provided in an upper-surface peripheral edge part of the semiconductor element 122 is connected to an electrode region of the wiring layer 140 by a gold wire 123, using the wire bonding method. Subsequently, the semiconductor element 120 and the semiconductor element 122 are sealed by a sealing resin layer 180, using the transfer mold method.

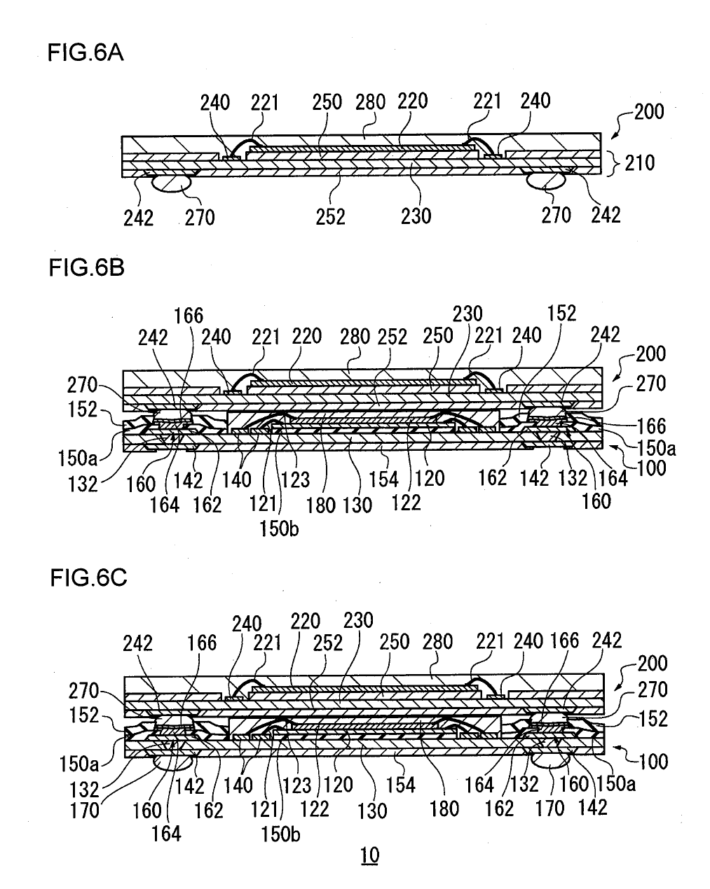

Then, as shown in FIG. 6A, the above-described second semiconductor module 200 is prepared.

Then, as shown in FIG. 6B, a reflow process is performed with the second semiconductor module 200 mounted on top of the first semiconductor module 100. That is, in this reflow process, the solder balls 270 join the first electrode portions 160 and the second electrode portions 242 together. As a result, the first electrode portions 160 and the second electrode portions 242 are electrically coupled to each other.

Then, as shown in FIG. 6C, solder balls 170 are mounted on third electrodes 142 in openings provided in the third insulating layer 154.

A semiconductor device 10 according to the first embodiment is manufactured through the above-described processes.

By employing the semiconductor device 10 according to the first embodiment, the following advantageous effects are achieved. That is, in the first semiconductor module 100, the height of the first electrode portion 160 is so raised as to be higher than the wiring layer 140. Accordingly, when the second semiconductor module 200 is mounted on top of the first semiconductor module 100, the bottom face of the second semiconductor module 200 does not interfere with the top face of the first semiconductor module 100 and the size of the solder ball 270 is made smaller. As a result, the area of the solder ball 270 bonded to and in contact with the first electrode portion 160 and the second electrode portion 242 can be reduced and therefore the pitch of the solder balls 270 can be made narrower when the solder balls 270 are mounted.

Also, the shape of the second conductor 164 constituting the first electrode portion 160 is determined by the shape of openings provided in the first insulating layer 150a and the second insulating layer 152. Thus, the second conductor 164 can be formed into a predetermined shape without patterning the second conductor 164.

Also, the second conductor 164 is formed in a region provided in the opening of the first insulating layer 150a so that the diameter of the second conductor 164 is smaller than the region provided in the opening of the second insulating layer 152. Thus, the amount of copper required for the second conductor 164 is reduced and therefore the manufacturing cost of the semiconductor device 10 can be reduced.

### Second Embodiment

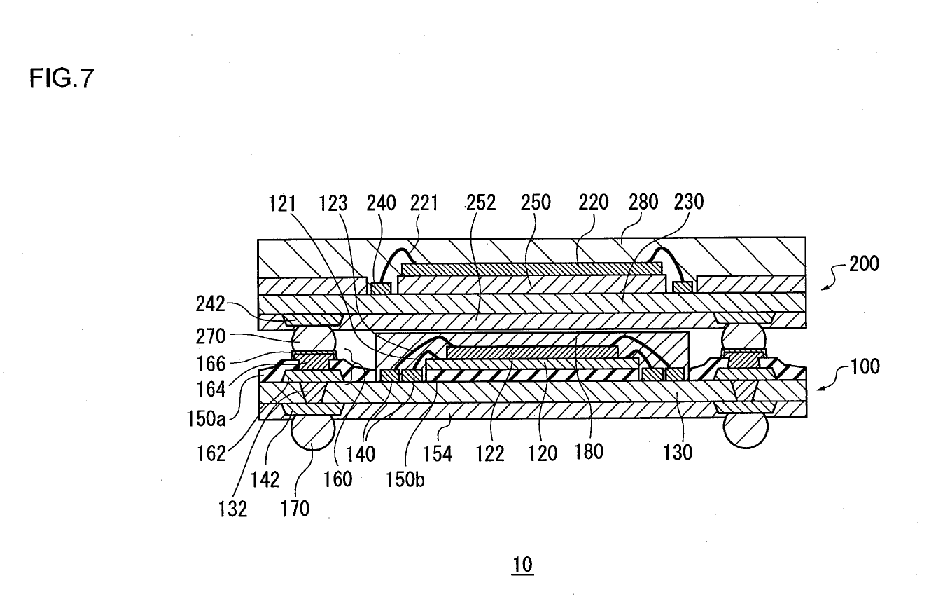

FIG. 7 is a schematic cross-sectional view showing a structure of a semiconductor device 10 according to a second embodiment. The structure of the semiconductor device 10 according to the second embodiment is similar to that of the first embodiment, except for a structure where the second insulating layer 152 of FIG. 1 is not provided.

Similar to the semiconductor device 10 according to the first embodiment, the semiconductor device 10 according to the second embodiment can reduce the area occupied by the solder balls 270 and the first electrode portions 160 and makes the first electrode portions 160 narrower. Hence, miniaturization and higher density of the semiconductor device 10 can be attained.

Besides, by employing the semiconductor device 10 according to the second embodiment, the process of forming the second insulating layer 152 is omitted, so that the manufacturing process for the semiconductor device 10 can be simplified.

### Third Embodiment

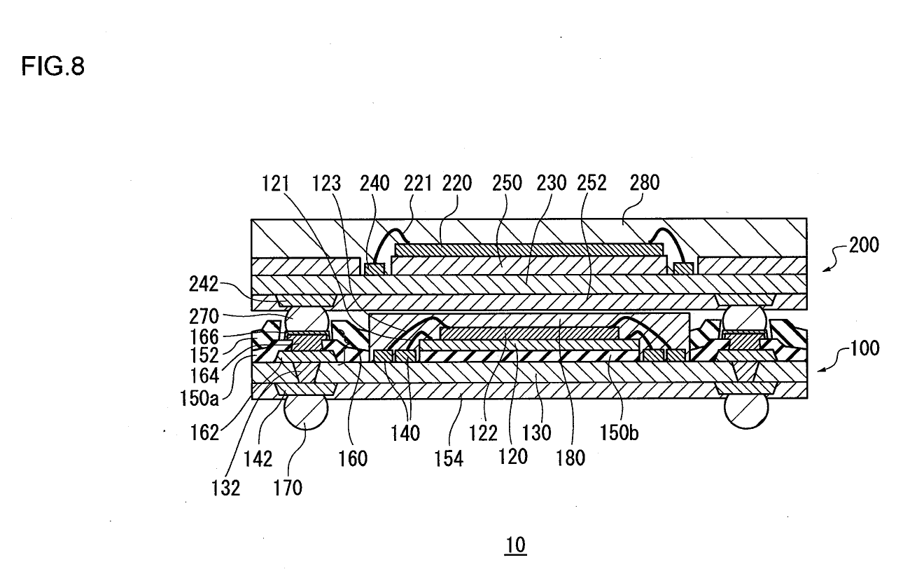

FIG. 8 is a schematic cross-sectional view showing a structure of a semiconductor device 10 according to a third embodiment. The semiconductor device 10 according to the third embodiment is structured such that a second insulating layer 152 is added to the semiconductor device 10 according to the second embodiment. In contrast to the second embodiment, there is a gap (space) between the first electrode portion 160 and the side wall of the second insulating layer 152, and the second insulating layer 152 and the first electrode portion 160 do not overlay with each other in the third semiconductor device 10.

Similar to the semiconductor device 10 according to the first embodiment, the area occupied by the solder balls 270 and the first electrode portions 160 can be reduced and the first electrode portions 160 can be made narrower by employing the semiconductor device 10 according to the third embodiment. Hence, miniaturization and higher density of the semiconductor device 10 can be attained.

Besides, by employing the semiconductor device 10 according to the third embodiment, the flow of the solder balls 270 is controlled when the solder balls 270 are melted by a reflow process. This prevents the adjacent solder balls 270 from being short-circuited with each other, so that the reliability of the semiconductor device 10 can be improved. Also, the melted solder enters the space between the first electrode portion 160 and the side wall of the second insulating layer 152, thereby increase a contact area between the solder ball 270 and the first electrode portion 160. Thus, the adhesion between the solder ball 270 and the electrode portion 160 improves.

### Fourth Embodiment

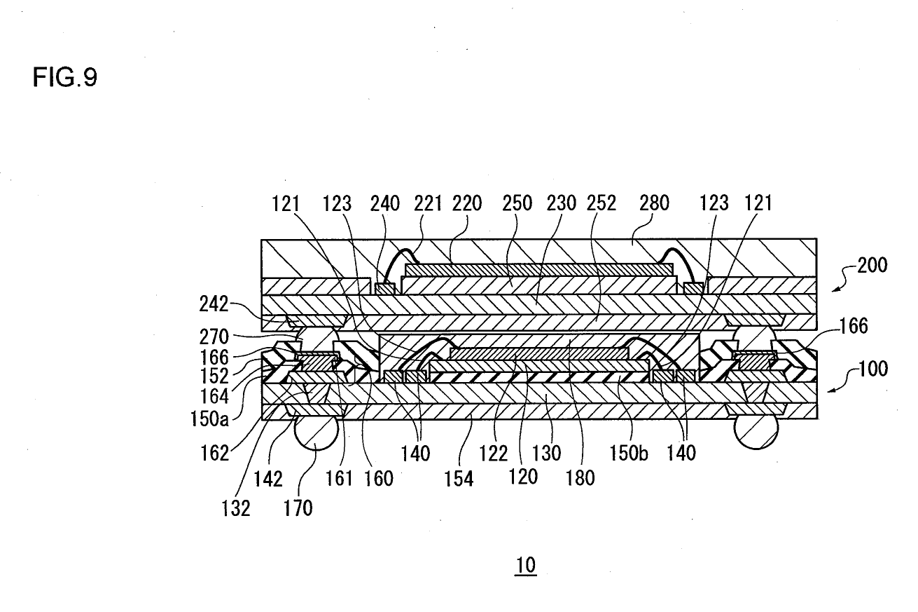

FIG. 9 is a schematic cross-sectional view showing a structure of a semiconductor device 10 according to a fourth embodiment. Similar to the third embodiment, the semiconductor device 10 according to the fourth embodiment is structured such that the second insulating layer 152 is added to the semiconductor device 10 according to the second embodiment. The fourth embodiment differs from the third embodiment in the feature that the second insulating layer 152 overlaps with the first electrode portion 160 in an upper-surface peripheral edge region of the first electrode portion 160.

By employing the semiconductor device 10 according to the fourth embodiment, the area occupied by the solder balls 270 and the first electrode portions 160 can be reduced and the first electrode portions 160 can be made narrower. Hence, miniaturization and higher density of the semiconductor device 10 can be attained.

Besides, by employing the semiconductor device 10 according to the fourth embodiment, the upper-surface peripheral edge region of the first electrode portion 160 is held down by the second insulating layer 152. This structure prevents an extended part 161 of the first electrode portion 160 from being separated from the second insulating layer 152.

### Fifth Embodiment

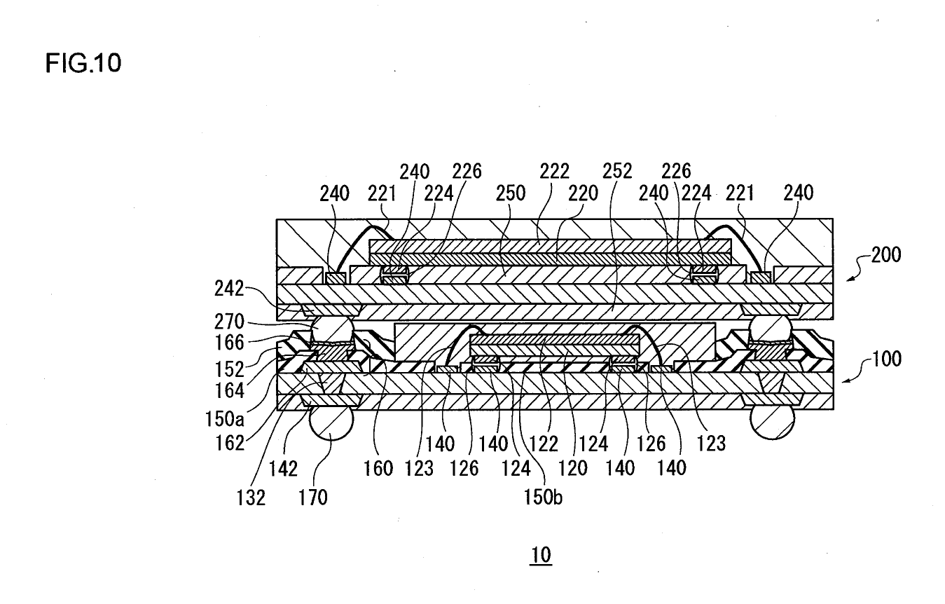

FIG. 10 is a schematic cross-sectional view showing a structure of a semiconductor device 10 according to a fifth embodiment. The structure of the semiconductor device 10 according to the fifth embodiment is similar to that of the first embodiment, except for how semiconductor elements in the first semiconductor module 100 and semiconductor elements in the second semiconductor module 200 are mounted.

In the first semiconductor module 100, a lower semiconductor element 120 is flip-chip connected. More specifically, a stud bump (element electrode) 124, which is made of Au (gold) and provided on the semiconductor element 120, and the wiring layer 140 provided on the insulating resin layer 130 are bonded together by the solder 126. On the other hand, similar to the first embodiment, an upper semiconductor element 122 is wire-bonded using the gold wire 123.

In the second semiconductor module 200, similar to the first semiconductor module 100, a stud bump (element electrode) 224, which is made of Au (gold) and provided on a semiconductor element 220, and the wiring layer 240 provided on the insulating resin layer 230 are bonded together by the solder 226. On the other hand, similar to the first embodiment, an upper semiconductor element 222 is wire-bonded using the gold wire 221.

By employing the semiconductor device 10 according to the fifth embodiment, the first electrode portions 160 can be made narrower as described above. Hence, even though the number of solder balls 270 required for the PoP increases as a result of the increased number of semiconductor elements mounted on the second semiconductor module 200, the PoP structure can be achieved while miniaturization of the semiconductor device 10 is attained.

### Sixth Embodiment

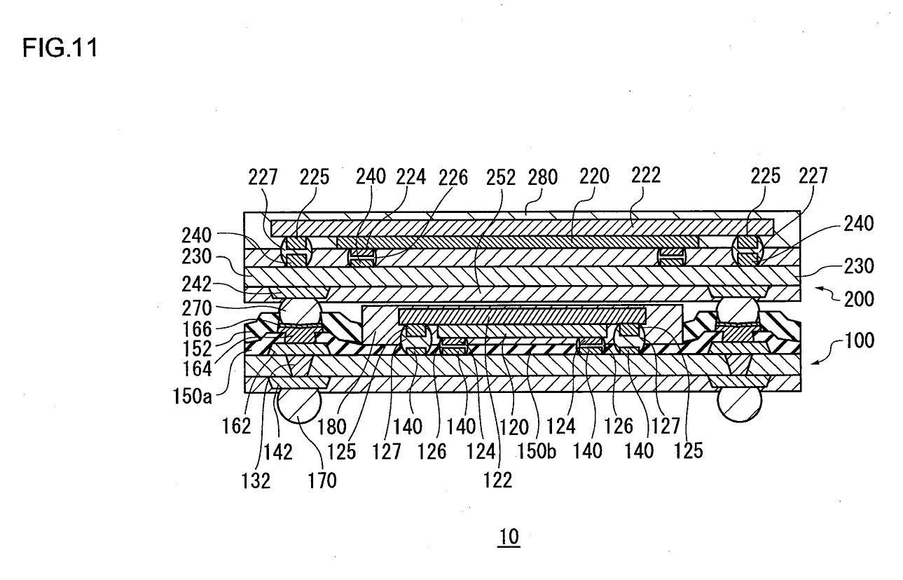

FIG. 11 is a schematic cross-sectional view showing a structure of a semiconductor device 10 according to a sixth embodiment. The structure of the semiconductor device 10 according to the sixth embodiment is similar to that of the fifth embodiment, except for how an upper semiconductor element in the first semiconductor module 100 and an upper semiconductor element in the second semiconductor module 200 are mounted.

In the first semiconductor module 100, an upper semiconductor element 122 is flip-chip connected. More specifically, the upper semiconductor element 122 is larger in area than the lower semiconductor element 120, and a peripheral edge part of the upper semiconductor element 122 extends and protrudes above the lower semiconductor element 120. A stud bump (element electrode) 125, which is made of Au (gold) and provided on an underside of a protruding part of the upper semiconductor element 122, and the wiring layer 140 provided on the insulating resin layer 130 are bonded together by a solder 127.

Similarly, in the second semiconductor module 200, an upper semiconductor element 222 is flip-chip connected. More specifically, the upper semiconductor element 222 is larger in area than the lower semiconductor element 220, and a peripheral edge part of the upper semiconductor element 222 extends and protrudes above the lower semiconductor element 220. A stud bump (element electrode) 225, which is made of Au (gold) and provided on an underside of a protruding part of the upper semiconductor element 222, and the wiring layer 240 provided on the insulating resin layer 230 are bonded together by a solder 227.

The semiconductor device 10 according to the sixth embodiment achieves the same advantageous effects as those achieved by the semiconductor device 10 according to the fifth embodiment.

In the first to sixth embodiments, miniaturization and higher density of the semiconductor module having a PoP structure is attained by adjusting the height of the first electrode portion 160 in the first semiconductor module 100. In contrast thereto, in seventh to tenth embodiments, miniaturization and higher density of the semiconductor module having a PoP structure is attained by adjusting the height of the second electrode portion 242 in the second semiconductor module 200.

### Seventh Embodiment

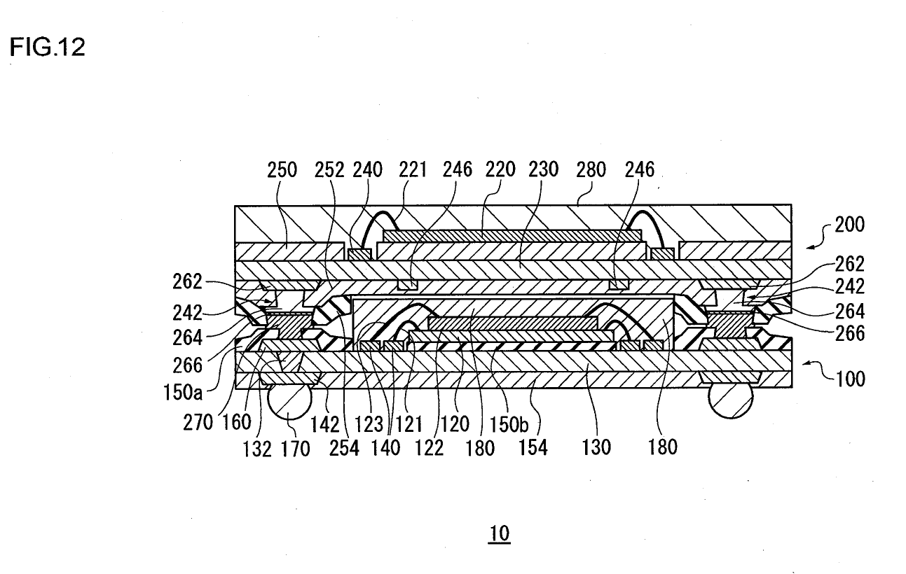

FIG. 12 is a schematic cross-sectional view showing a structure of a semiconductor device 10 according to a seventh embodiment. The first electrode portion 160 in the first semiconductor module 100 belongs to the same layer to which the wiring layer 140 belongs, and this first electrode portion 160 has the same thickness as that of the wiring layer 140. Also, the seventh embodiment differs from the first embodiment in that the second insulating layer 152 of FIG. 1 is not formed in the first semiconductor module 100.

On the other hand, in the second semiconductor module 200, the second electrode portion 242 has a similar structure to that of the first electrode 160 of FIG. 1. In other words, the second electrode portion 242 includes a third conductor 262, a fourth conductor 264, and a gold plating layer 266.

The third conductor 262 belongs to the same layer to which a wiring layer 246, provided on an underside of an insulating resin layer 230, belongs and this third conductor 262 has the same thickness as that of the wiring layer 246.

The fourth conductor 264 is filled into a space formed by a lower surface of the third conductor 262, a side wall of a fifth insulating layer 252 and a side wall of a sixth insulating layer 254. In other words, the fourth conductor 264 is completely filled into an opening provided in the fifth insulating layer 252 and is partially filled into an opening provided in the sixth insulating layer 254. The diameter of the opening provided in the sixth insulating layer 254 is greater than that of the opening provided in the fifth insulating layer 252. Thus, the diameter of the fourth conductor 264 is such that the diameter of the second conductor 164 in a region provided in the opening of the sixth insulating layer 254 is greater than that in a region provided in the opening of the fifth insulating layer 252. In other words, the cross section of the fourth conductor 264 is of a T-shape or mushroom shape.

Also, the gold plating layer 266 such as a Ni/Au layer is formed on a lower surface of the fourth conductor 264. Provision of the gold plating layer 266 suppresses the oxidation of the fourth conductor 264.

The semiconductor device 10 according to the seventh embodiment achieves the same advantageous effects as those achieved by the semiconductor device 10 according to the first embodiment.

### Eighth Embodiment

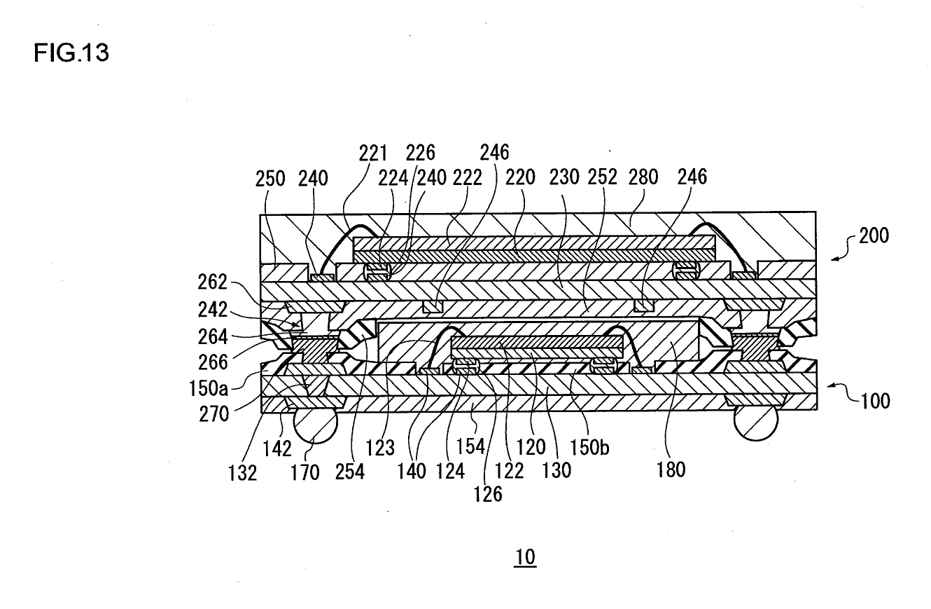

FIG. 13 is a schematic cross-sectional view showing a structure of a semiconductor device 10 according to an eighth embodiment. In terms of the package structure of the first semiconductor module 100 and the second semiconductor module 200, the semiconductor device 10 according to the eighth embodiment corresponds to the sixth embodiment. The bonding structure in the first semiconductor module 100 and the second semiconductor module 200 is similar to that of the seventh embodiment.

The semiconductor device 10 according to the eighth embodiment achieves the same advantageous effects as those achieved by the semiconductor device 10 according to the seventh and sixth embodiments.

### Ninth Embodiment

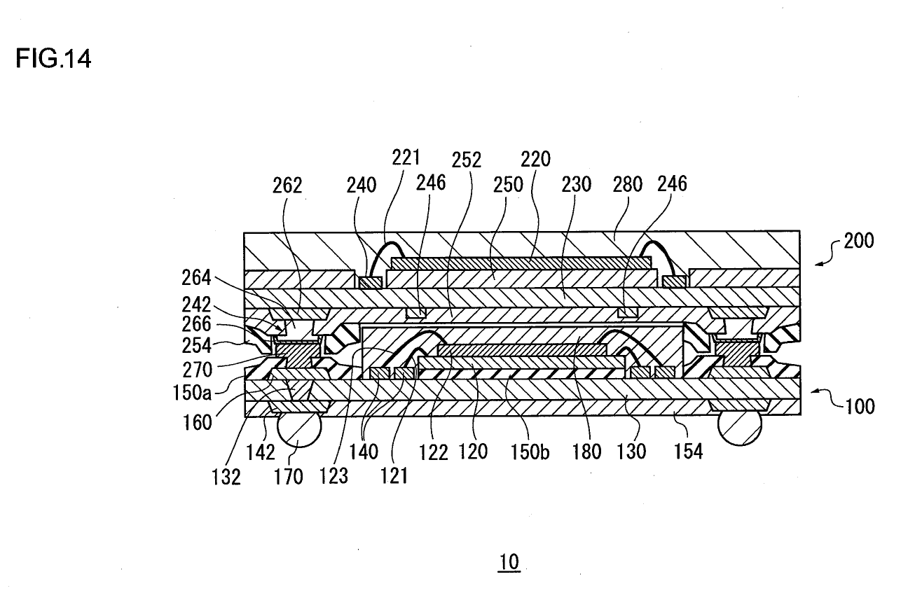

FIG. 14 is a schematic cross-sectional view showing a structure of a semiconductor device 10 according to a ninth embodiment. In terms of the second electrode portion 242 and the its peripheral structure thereof, the semiconductor device 10 according to the ninth embodiment corresponds to the third embodiment. That is, a space (gap) is provided between the sixth insulating layer 254 and the second electrode portion 242.

The semiconductor device 10 according to the ninth embodiment achieves the same advantageous effects as those achieved by the semiconductor device 10 according to the seventh and third embodiments.

### Tenth Embodiment

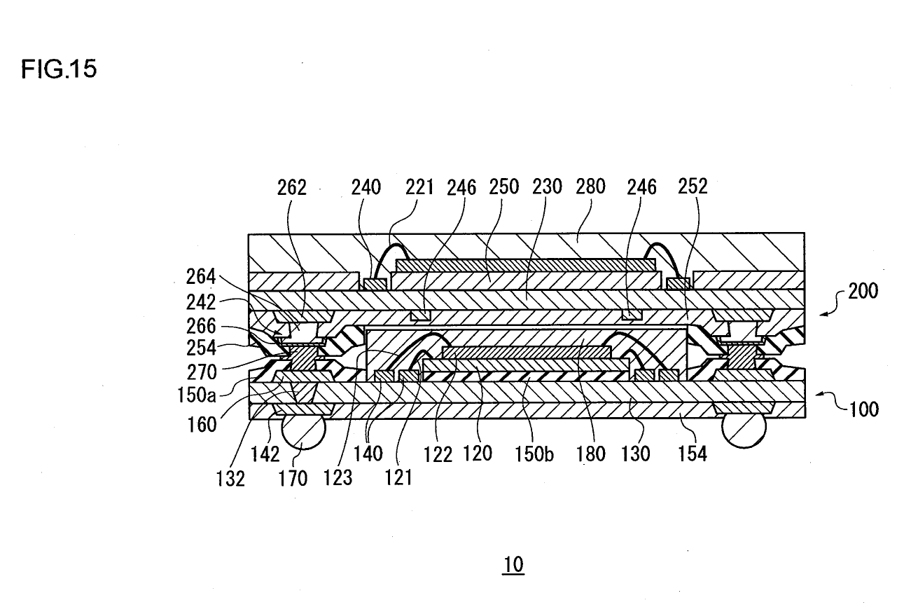

FIG. 15 is a schematic cross-sectional view showing a structure of a semiconductor device 10 according to a tenth embodiment. In terms of the second electrode portion 242 and the peripheral structure thereof, the semiconductor device 10 according to the tenth embodiment corresponds to the fourth embodiment. That is, the sixth insulating layer 254 overlaps with the second electrode portion 242 in a lower-surface peripheral edge region of the second electrode portion 242.

The semiconductor device 10 according to the tenth embodiment achieves the same advantageous effects as those achieved by the semiconductor device 10 according to the seventh and fourth embodiments.

### Eleventh Embodiment

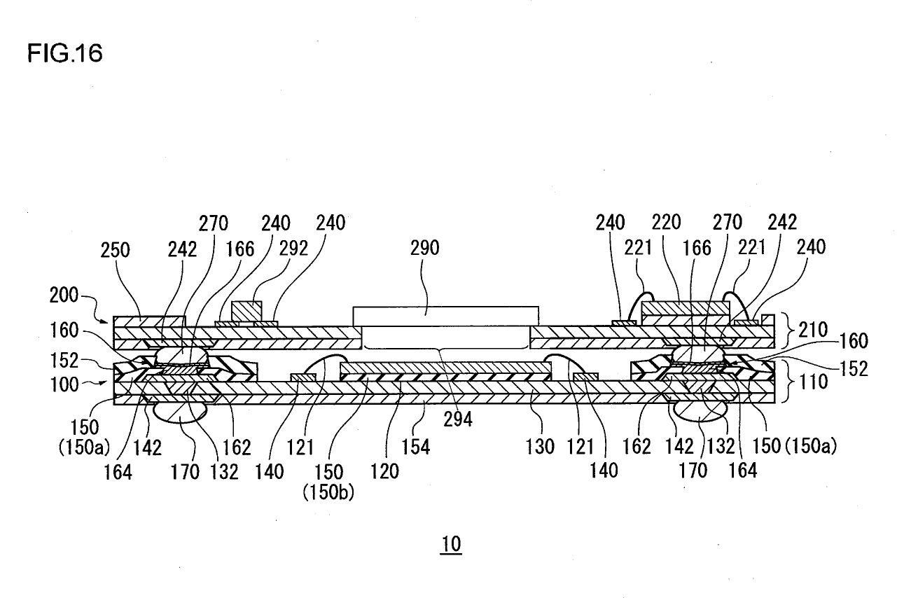

FIG. 16 is a schematic cross-sectional view showing a structure of a semiconductor device 10 according to an eleventh embodiment. The semiconductor device 10 according to the present embodiment is a camera module used for an image pickup apparatus such as a digital still camera, a digital video camera or a camera incorporated into a mobile phone. In the semiconductor device 10 according to the present embodiment, the semiconductor element 120 is a light receiving element such as a CMOS image sensor. An element electrode (not shown) provided on the semiconductor element 120 and a predetermined region of the wiring layer 140 are wire-bonded to each other using a gold wire 121. In the semiconductor element 120, photodiodes are formed in a matrix, and each photodiode photoelectrically converts light into charge quantity in response to the amount of light received by the each photodiode so as to output it as a pixel signal.

The semiconductor element 220 mounted on the element mounting board 210 is a driver IC and has a function of controlling the exposure timing of each image pickup element of the semiconductor element 120, the output timing of the pixel signal and the like. Also, chip components such as capacitors and resistors are mounted on the electrode mounting board 210. An element electrode (not shown) provided on the semiconductor element 220 and a predetermined region of the wiring layer 240 are wire-bonded to each other using a gold wire 221.

The element mounting board 210 has an opening 294 in alignment with a light-receiving region of the semiconductor element 120. Each image pickup element of the semiconductor element 120 receives the light incident from the opening 294 and outputs the pixel signal. An optical filter 290 for clocking and closing up the opening 294 is mounted in the element mounting board 210. The optical filter 290 cuts off the light having a specific wavelength such as infrared beam.

The structure of interconnection between the element mounting board 110 and the element mounting board 210 is similar to that in the first embodiment. Thus, the semiconductor device 10 according to the eleventh embodiment achieves the same advantageous effects in the camera module as those achieved by the first embodiment.

### Twelfth Embodiment

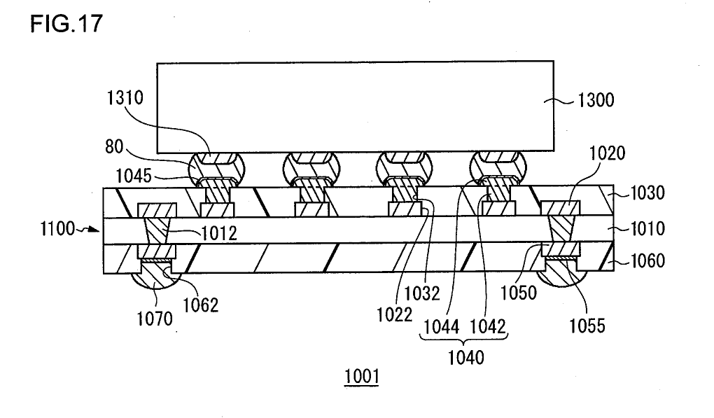

FIG. 17 is a schematic cross-sectional view showing a structure of an element mounting board 1100 and a semiconductor module 1001 according to a twelfth embodiment. The semiconductor module 1001 is of a structure such that a semiconductor element 1300 is flip-chip connected to the element mounting board 1100.

The electrode mounting board 1100 includes a substrate (base material) 1010, wiring layers 1020 provided on one main surface of the substrate 1010, a first insulating layer 1030, and electrodes 1040. The electrode mounting board 1100 further includes lower-surface-side wiring layers 1050 provided on the other main surface of the substrate 1010, and a lower-surface-side insulating layer 1060.

The base material 1010 may be formed of a thermosetting resin such as a melamine derivative (e.g., BT resin), liquid-crystal polymer, epoxy resin, PPE resin, polyimide resin, fluorine resin, phenol resin or polyamide bismaleimide, or the like.

The wiring layer 1020 has a predetermined pattern and is provided on one main surface of the substrate 1010 (on a mounting surface of the semiconductor element 1300 in the present embodiment). The wiring layer 1020 is formed of a conductive material such as copper. An electrode forming region 1022, in which the electrode 1040 is formed, is provided in a predetermined position of the wiring layer 1020.

The lower-surface-side wiring 1050 having a predetermined pattern is provided on the other main surface of the substrate 1010. The lower-surface-side wiring layer 1050 is formed of a conductive material such as copper. The thickness of the lower-surface-side wiring layer 1050 is 10 μm to 25 μm, for instance. A gold plating layer 1055 such as a Ni/Au layer is formed on a surface of the lower-surface-side wiring layer 1050 in a lower-surface-side opening 1062 described later. Provision of the gold plating layer 1055 suppresses the oxidation of the lower-surface-side wiring layer 1050. If the Ni/Au layer is to be formed as the gold plating layer 1055, the thickness of Ni layer will be 1 μm to 15 μm, for instance, and the thickness of Au layer will be 0.03 μm to 1 μm, for instance.

Via conductors 1012, which penetrate the substrate 1010, are provided in predetermined positions of the substrate 1010. The via conductor 1012 is formed by a copper plating, for instance. The wiring layer 1020 and the lower-surface-side wiring layer 1050 are electrically connected to each other through the via conductor 1012.

The first insulating layer 1030 is provided on the periphery of the electrode forming region 1022 of the wiring layer 1020. In the present embodiment, the first insulating layer 1030 is so formed as to cover the wiring layers 1020, and the first insulating layer 1030 prevents the oxidation and the like of the wiring layers 1020. The first insulating layer 1030 has a first opening 1032 so formed that the electrode forming region 1022 is exposed there. The electrode 1040 is connected to the electrode forming region 1022 within the first opening 1032. The first insulating layer 1030 is formed of a photo solder resist, for instance. The thickness of the first insulating layer 1030 is 10 μm to 50 μm, for instance.

The electrode 1040, which has an embedded portion 1042 and a protrusion 1044, is electrically connected to the electrode forming region 1022 in the first opening 1032. A gold plating layer 1045 such as a Ni/Au layer is formed on a surface of the protrusion 1044. Provision of the gold plating layer 1045 suppresses the oxidation of the protrusion 1044. If the Ni/Au layer is to be formed as the gold plating layer 1045, the thickness of Ni layer will be 1 μm to 15 μm, for instance, and the thickness of Au layer will be 0.03 μm to 1 μm, for instance.

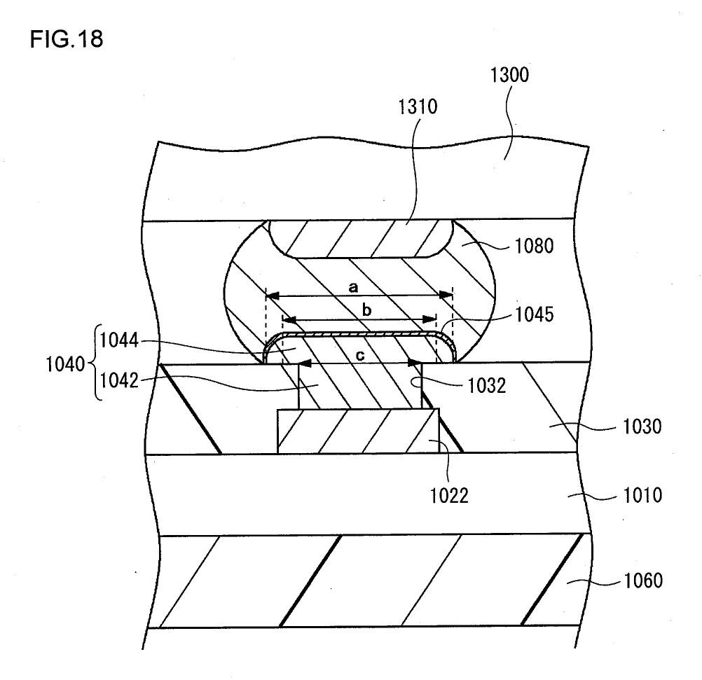

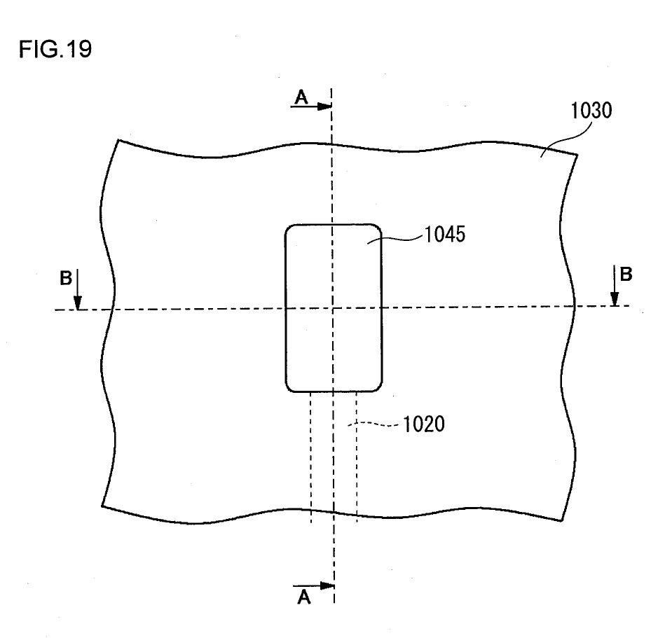

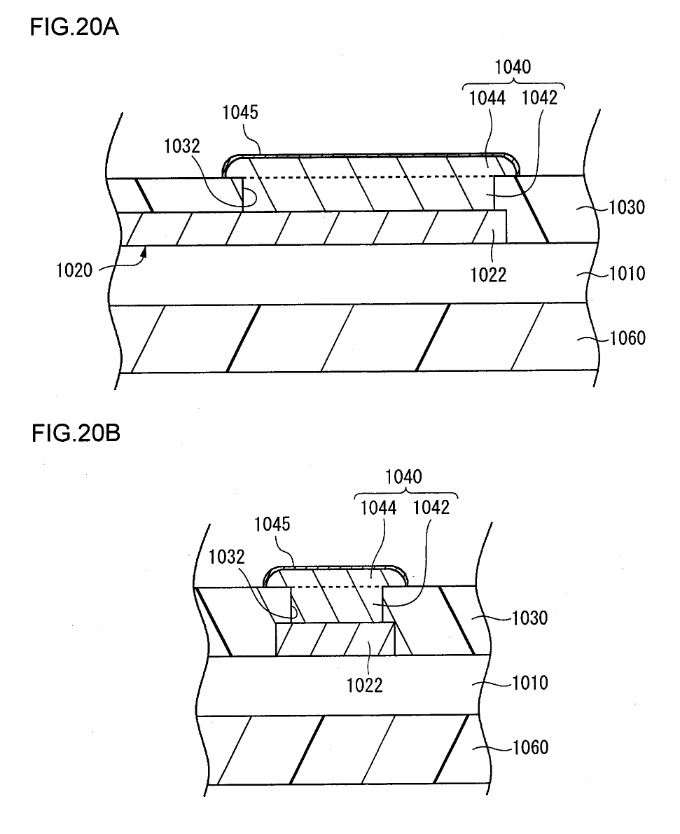

A detailed description is given hereunder of the electrode 1040 with reference to FIG. 18 to FIG. 20B. FIG. 18 is a partially enlarged view showing a structure of the electrode 1040 and its periphery thereof in a semiconductor module 1001. FIG. 19 is a partial plan view showing a structure of an element mounting board 1100. FIG. 20A is a schematic cross-sectional view taken along line A-A of FIG. 19, and FIG. 20B is a schematic cross-sectional view taken along line B-B of FIG. 19.

As shown in FIG. 18, the embedded portion 1042 of the electrode 1040 fills in the first opening 1032 and is electrically connected to the electrode forming region 1022. A protrusion 1044 is formed above the embedded portion 1042 and is formed integrally with the embedded portion 1042. The protrusion 1044 protrudes above an upper surface of the periphery of the first opening 1032 of the first insulating layer 1030. Also, the protrusion 1044 extends horizontally on the first insulating layer 1030 and therefore a peripheral edge of the protrusion 1044 lies external to a peripheral edge of the embedded portion 1042, as viewed from above the electrode 1040 (from above in FIG. 18). In other words, the embedded portion 1042 is located inside the peripheral edge of the protrusion 1044, as viewed from above the electrode 1040; the width a of the protrusion 1044 is greater than the width c of the embedded portion 1042, as viewed in a vertical section passing through a center axis of the electrode 1040. In other words, the cross section of the electrode 1040 is of a T-shape or mushroom shape. Though the thickness of the gold plating layer 1045 is not taken into account here, the same structure and operation work even if the thickness of the gold plating layer 1045 is taken into consideration instead.

In the element mounting board 1100 according to the present embodiment, the periphery of a flat part in an upper surface of the protrusion 1044 may lie external to the peripheral edge of the embedded portion 1042, as viewed from above the electrode 1040. In other words, the width b of the flat part in the upper surface of the protrusion 1044 is greater than the width c of the embedded portion 1042, as viewed in the vertical section passing through a center axis of the electrode 1040. The height of the embedded portion 1042 and the protrusion 1044 is in a range of 5 μm to 20 μm, for instance, whereas the width a of the protrusion 1044, the width b of the flat part and the width c of the embedded portion 1042 are 50 μm, 45 μm and 40 μm, respectively, for instance.

A positional relationship between the wiring layer 1020 and the electrode 1040 is now described. As shown in FIG. 19, a protrusion covered with the gold plating 1045 is exposed on an upper surface of the first insulating layer 1030, as viewed planarly, in a predetermined end region of the wiring layer 1020 covered with the first insulating layer 1030. As shown in FIG. 20A, a cross section of the element mounting board 1100 indicates that the electrode forming region 1022 is formed in an end region of the wiring layer 1020 and that the electrode 1040 is provided on the electrode forming region 1022. More specifically, as shown in FIGS. 20A and 20B, the embedded portion 1042 of the electrode 1040 is provided in the opening 1032 formed in a region corresponding to the electrode forming region 1022 of the first insulating layer 1030; the protrusion 1044, which is formed integrally with the embedded portion 1042, is provided above the embedded portion 1042 and protrudes above the upper surface of the first insulating layer 1030.

Referring back to FIG. 17, the lower-surface-side insulating layer 1060 is provided on the other main surface of the substrate 1010 in such a manner as to cover the lower-surface-side wiring layers 1050, and the lower-surface-side insulating layer 1060 prevents the oxidation and the like of the lower-surface-side wiring layers 1050. The lower-surface-side opening 1062, in which a solder ball 1070 is mounted, in a land area of the lower-surface-side wiring layer 1050 is provided in the lower-surface-side insulating layer 1060. The solder ball 1070 is connected to the lower-surface side wiring layer 1050, via the gold plating layer 1055, in the lower-surface-side opening 1062 provided in the lower-surface-side insulating layer 1060. The semiconductor module 1001 is connected to a not-shown printed wiring board through the medium of the solder balls 1070. The lower-surface-side insulating layer 1060 is formed of a photo solder resist, for instance, and the thickness of the lower-surface-side insulating layer 1060 is 10 μm to 50 μm, for instance.

The semiconductor element 1300 is mounted on the element mounting board 1100 having the above-described structure, thereby forming the semiconductor module 1001. More specifically, the semiconductor element 1300 is flip-chip connected to the element mounting board 1100 in such a manner that not-shown element electrodes provided in the semiconductor element 1300 and the protrusions 1044 of the electrodes 1040 in the element mounting board 1100 are bonded together by the solder balls 1080.

The element electrodes provided in semiconductor element 1300 are disposed counter to the electrodes 1040, respectively, and a stud bump made of gold (Au) is provided on the surface of the element electrode. An example of the semiconductor element 1300 is a semiconductor chip such as an integrated circuit (IC) or a large-scale integrated circuit (LSI). Aluminum (Al) may be used for the element electrode, for instance.

Though not shown in the Figures, an underfill material formed of epoxy resin, for instance, may be filled into a gap between the semiconductor element 1300 and the element mounting board 1100. The underfill material protects a joint between the element electrode and the electrode 1040. Also, a sealing resin layer formed of epoxy resin or the like may seal the semiconductor element 1300 by using a transfer mold method.

In the semiconductor module 1001 according to the present embodiment, the solder ball 1080 is joined to the protrusion 1044 of the electrode 1040, and the electrodes 1040 and the semiconductor element 1300 are electrically connected via the solder balls 1080. The protrusion 1044 extends horizontally on the first insulating layer 1030, and the peripheral edge of the protrusion 1044 lies external to the peripheral edge of the embedded portion 1042, as viewed from above the electrode 1040. Thus, it is possible to secure a wider connection area with the element electrode via the solder ball 1080. Accordingly, the connection reliability between the element mounting board 1100 and the semiconductor element 1300 can be improved.

(Method for Fabricating an Element Mounting Board and a Semiconductor Module)

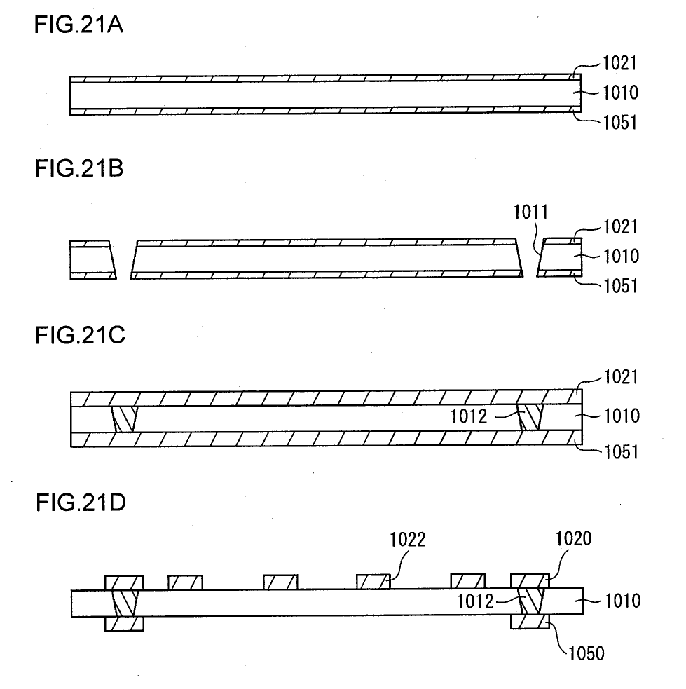

A method for manufacturing a semiconductor module 1001 according to the twelfth embodiment is described with reference to FIG. 21A to FIG. 23C. FIGS. 21A to 21D, FIGS. 22A to 22D and FIGS. 23A to 23C are cross-sectional views showing processes in the method for fabricating the semiconductor module 1001.

As shown in FIG. 21A, a substrate (base material) 1010 to which a copper foil 1021 is attached to one main surface of thereof and a copper foil 1051 is attached to the other main surface thereof is first prepared.

Then, as shown in FIG. 21B, predetermined regions of the substrate 1010 and the copper coils 1021 and 1051 are drilled by a drilling process, such as a drill or laser process, so as to form via holes 1011 there.

Then, as shown in FIG. 21C, the via holes 1011 are filled with copper by using an electroless plating method and an electrolytic plating method, thereby forming via conductors 1012. At the same time, the copper foils 1021 and 1051 provided on the main surfaces thereof are thickened.

As shown in FIG. 21D, wiring layers 1020, of a predetermined pattern, having electrode forming regions 1022 are formed on one main surface of the substrate 1010, using known photolithography method and etching method. Also, lower-surface-side wiring layers 1050 are formed on the other main surface of the substrate 1010, using known photolithography method and etching method.

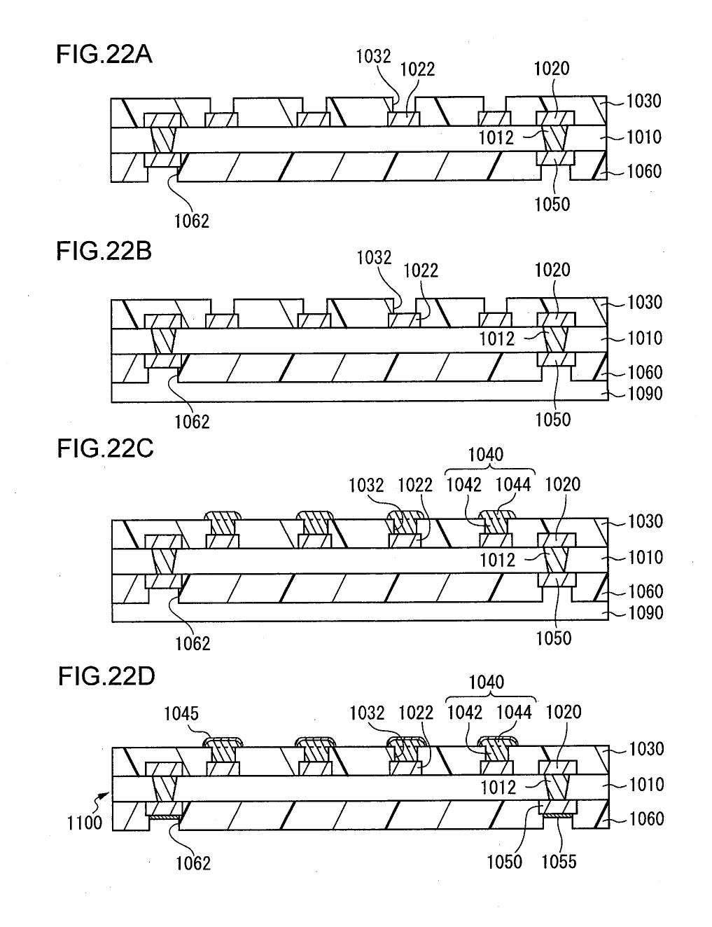

Then, as shown in FIG. 22A, a photo solder resist is laminated on the main surface of the substrate 1010 and then a first insulating layer 1030 having first openings 1032 is formed using known photolithography method and etching method. Here, in each of the first openings 1032, an electrode forming region 1020 of the wiring layer 1020 is exposed. Similar to the main surface of the substrate 1010, a photo solder resist is laminated on the other main surface of the substrate 1010 and then a lower-surface-side insulating layer 1060 having lower-surface-side openings 1062 are formed using known photolithography method and etching method. Here, in each of the lower-surface-side openings 1062, a land area of a lower-surface-side wiring layer 1050 is exposed on a predetermined region.

As shown in FIG. 22B, a mask 1090 is laminated on one main surface of the lower-surface-side insulating layer 1060 opposite to the substrate 1010 in such a manner as to cover this opposite-side main surface thereof in its entirety.

Then, as shown in FIG. 22C, copper is filled above the electrode forming regions 1022, using the electrolytic plating method. In this plating process, copper is first gradually filled into the first openings 1032 provided in the first insulating layers 1030 and then the first openings 1032 are completely filled with copper, thereby forming embedded portions 1042. After this, the copper is further built up by the plating and therefore the copper protrudes above the upper surface of a periphery of the first opening 1032 of the insulating layer 1030. At the same time, the peripheral edge of copper spreads toward a region external to the first opening 1032, as viewed from above the first insulating layer 1030, thereby forming a protrusion 1044. The cross section or profile of the electrode 1040 is of a T-shape or mushroom shape. The size of the protrusion 1044 including the width a (see FIG. 18) and the width b (See FIG. 18) of the flat part in the upper surface of the protrusion 1044 may be adjusted, as appropriate, by adjusting the plating processing time.

Then, as shown in FIG. 22D, the plating mask 1090 is removed using a remover. Then, by using the electrolytic plating method, a gold plating layer 1045 is formed on a surface of the protrusion 1044, and a gold plating layer 1055 is formed in the land area of the lower-surface-side wiring layer 1050. An element mounting board 1100 according to the twelfth embodiment is manufactured through the above-described processes.

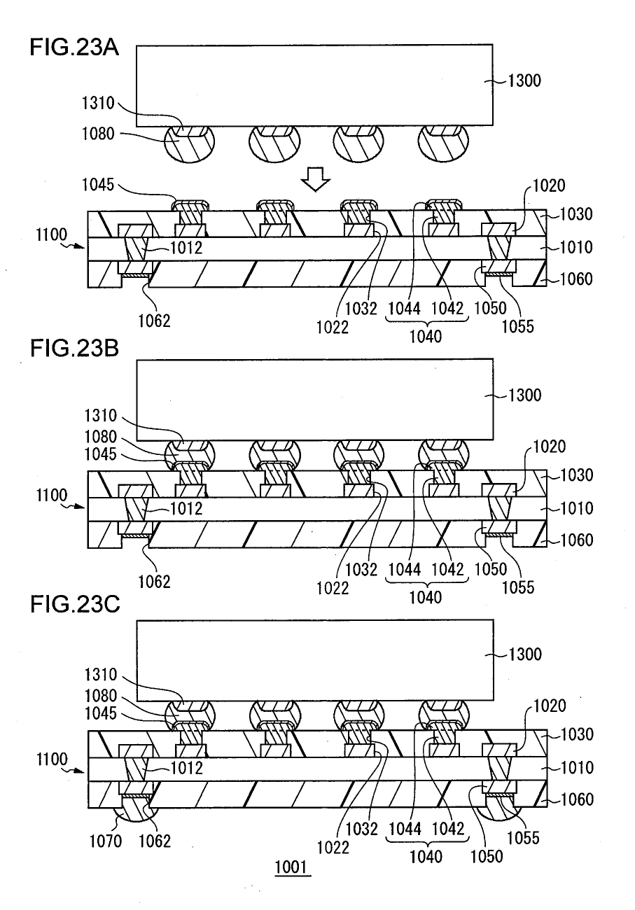

Then, as shown in FIG. 23A, a semiconductor element 1300 is prepared where stud bumps 1310 are provided in element electrodes and solder balls 1080 are mounted on the stud bumps 1310. Then the semiconductor element 1300 is mounted on the element mounting board 1100.

Then, as shown in FIG. 23B, a reflow process is performed with the semiconductor element 1300 mounted on the element mounting board 1100. That is, in this reflow process, the solder balls 270 are joined to the protrusions 1044 of the electrodes 1040 and thereby the first electrodes 1040 and the element electrodes are electrically coupled to each other.

Then, as shown in FIG. 23C, the solder balls 1070 are mounted on the lower-surface-side wiring layers 1050, in the lower-surface-side openings 1062 provided in the lower-surface-side insulating layer 1060.

A semiconductor module 1001 according to the twelfth embodiment is manufactured through the above-described processes. Though not shown in the Figures, an underfill material may be filled into a gap between the semiconductor element 1300 and the element mounting board 1100. Also, a sealing resin layer may seal the semiconductor element 1300 by using the transfer mold method.

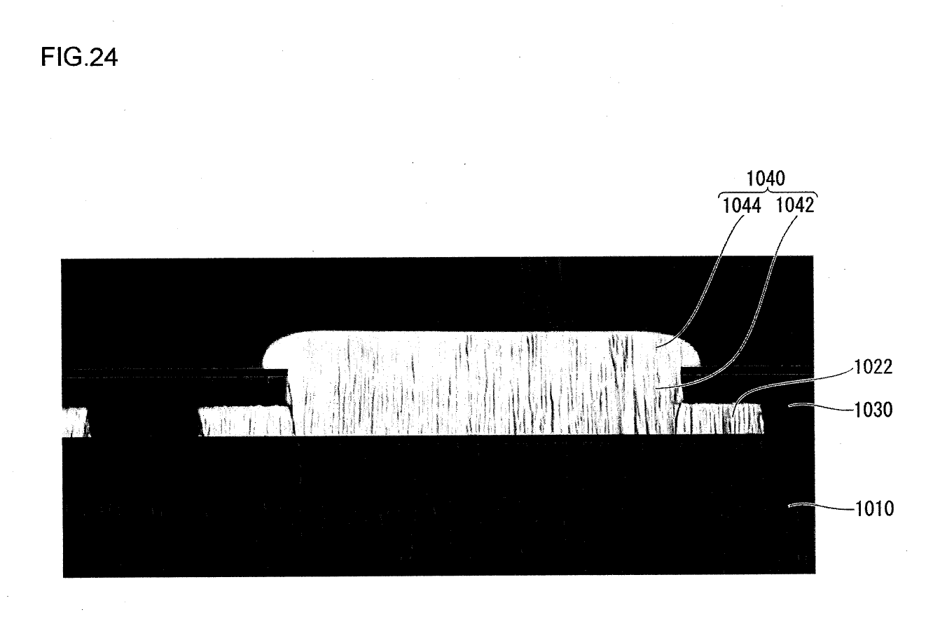

FIG. 24 is an SEM (scanning electron microscope) photographic image of the electrode 1040 of the element mounting board 1100, manufactured by the above-described fabrication method, and its surrounding area. As shown in FIG. 24, the protrusion 1044 of the electrode 1040 protrudes above the upper surface of the first insulating layer 1030 and extends horizontally, and the electrode 1040 is of a T-shape or mushroom shape as viewed in a cross section.

To sum up the operations of and the advantageous effects achieved by the arrangement thus far explained, the electrode 1040 formed on the electrode forming region 1022 of the wiring layer 1020 has (i) the embedded portion 1042 embedded in the first opening 1032 of the first insulating layer 1030 and (ii) the protrusion 1044 protruding above the periphery of the first opening 1032 of the first insulating layer 1030, in the element mounting board 1100 according to the twelfth embodiment. The electrode 1040 is so shaped that the peripheral edge of the protrusion 1044 lies external to the peripheral edge of the embedded portion 1042. Thus, the size (area) of the flat part on top of the electrode 1040 connected to the element electrode of the semiconductor element 1300 can be increased, so that connection reliability between the element mounting board 1100 and the semiconductor element 1300 can be improved.

In the element mounting board 1100 according to the twelfth embodiment, the electrode 1040 is so shaped that the peripheral edge of the flat part on top of the protrusion 1044 lies external to the peripheral edge of the embedded portion 1042. Thus, the size of the flat part on top of the electrode 1040 connected to the element electrode of the semiconductor element 1300 can be further increased, so that connection reliability between the element mounting board 1100 and the semiconductor element 1300 can be further improved.

In a conventional structure where a land area of the wiring layer and an element electrode are joined by a solder ball, the upper surface of the insulating layer is located above the upper surface of the wiring layer provided on a substrate, and an underfill material is filled in a space between the substrate and the semiconductor element. On the other hand, the arrangement according to the twelfth embodiment is such that the protrusion 1044 protruding above the first insulating layer 1030 is joined to the element electrode through the medium of the solder ball 1080, and the underfill material is filled in a space between the upper surface of the first insulating layer 1030 and the semiconductor element 1300. In the both structures, the underfill material passes through a passage formed by the upper surface of the insulating layer and one main surface of the semiconductor element disposed counter to this upper surface thereof. Thus, if the diameter of the solder balls are equal in the both structures, the passage of the underfill can be made larger in the twelfth embodiment and therefore the fluidity of the underfill will increase. Accordingly, it is possible to fill the space with the underfill more reliably and thereby the connection reliability between the element mounting board 1100 and the semiconductor element 1300 can be further improved.

If the distance between the semiconductor element and the element mounting board is set equal in both the conventional structure and the structure according to the twelfth embodiment, the distance between the electrode 1040 and the semiconductor element 1300 in the twelfth embodiment is shorter than that in the conventional structure. This is because the protrusion 1044 of the electrode 1040 protrudes above the upper surface of the first insulating layer 1030 in the semiconductor module 1001 according to the twelfth embodiment. As a result, the diameter of the solder ball 1070 can be made smaller and thus the pitch between the electrodes 1040 can be reduced. Hence, the size of the semiconductor module 1001 can be further reduced.

Also, by employing the fabrication method for fabricating the element mounting board 1100 according the twelfth embodiment, the etching process and the like are not carried out for the planarization of the upper surface of the electrodes 1040, so that the connection reliability between the element mounting board 1100 and the semiconductor element 1300 can be improved by the use of a simpler method. Also, the number of manufacturing processes for the element mounting board 1100 and the substrate 1010 is reduced and therefore the manufacturing process can be simplified.

### Thirteenth Embodiment

A semiconductor module according to a thirteenth embodiment differs from the twelfth embodiment in that a second insulating layer is provided. Hereinbelow, the present embodiment will be explained. Note that the other structural components and the fabrication process of the semiconductor module 1001 are basically the same as those in the twelfth embodiment. The same structural components are given the same reference numerals as those in the twelfth embodiment and the repeated description thereof is omitted as appropriate.

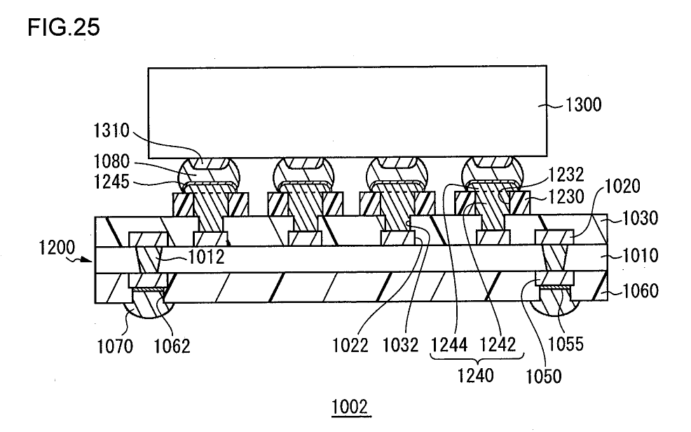

FIG. 25 is a schematic cross-sectional view showing a structure of an element mounting board 1200 and a semiconductor module 1002 according to the thirteenth embodiment. The element mounting board 1200 includes a substrate 1010, wiring layers 1020 provided on one main surface of the substrate 1010, second wiring layers 1230 and electrodes 1240. The element mounting board 1200 includes lower-surface-side wiring layers 1050 provided on the other main surface of the substrate 1010 and a lower-surface-side insulating layer 1060.

The second insulating layer 1230 is provided on the periphery of a first opening 1032 on the first insulating layer 1030. The second insulating layer 1230 has a second opening 1032 so formed that the electrode forming region 1022 is exposed there. The second insulating layer 1230 is formed of a photo solder resist, for instance. The thickness of the second insulating layer 1230 is 10 μm to 50 μm, for instance.

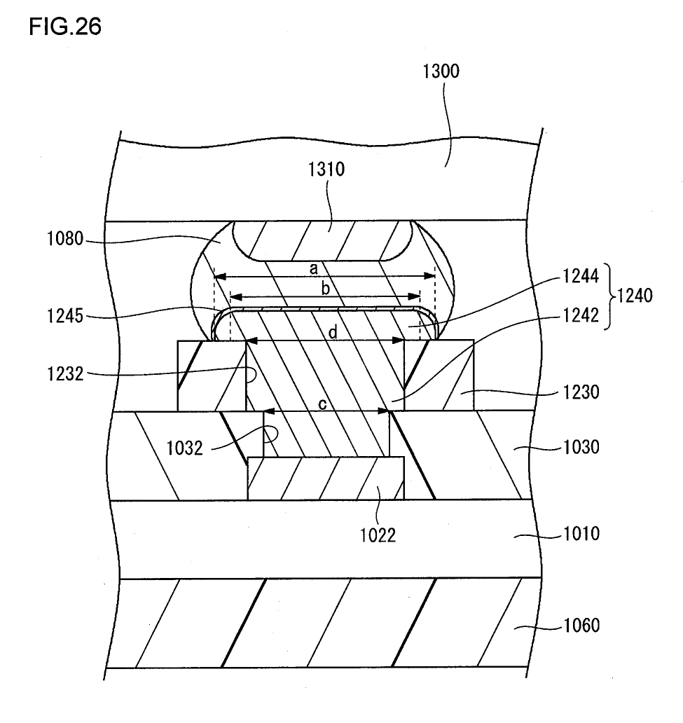

The electrode 1240, which has an embedded portion 1242 and a protrusion 1244, is electrically connected to the electrode forming region 1022 in the first opening 1032. A gold plating layer 1245 is formed on a surface of the protrusion 1244. A detailed description is now given of the electrode 1240 with reference to FIG. 26. FIG. 26 is a partially enlarged view showing a structure of the electrode 1240 and its periphery thereof in the semiconductor module 1002.

As shown in FIG. 26, the embedded portion 1242 of the electrode 1040 fills in the first opening 1032 and the second opening 1232, and is electrically connected to the electrode forming region 1022. A protrusion 2044 is formed above the embedded portion 1242 and is formed integrally with the embedded portion 1242. The protrusion 2044 protrudes above an upper surface of the periphery of the second opening 1232 of the second insulating layer 1230. Also, the protrusion 1244 extends horizontally on the second insulating layer 1230 and therefore a peripheral edge of the protrusion 1244 lies external to a peripheral edge of the embedded portion 1242, as viewed from above the electrode 1240 (from above in FIG. 26). In other words, the embedded portion 1242 is located inside the peripheral edge of the protrusion 1244, as viewed from above the electrode 1240; the width a of the protrusion 1244 is greater than the width d of the embedded portion 1242 in the second opening 1232, as viewed in a vertical section passing through a center axis of the electrode 1240.

In the element mounting board 1200 according to the present embodiment, the periphery of a flat part in an upper surface of the protrusion 1244 lies external to the peripheral edge of the embedded portion 1242, as viewed from above the electrode 1240. In other words, the width b of the flat part in the upper surface of the protrusion 1244 is greater than the width d of the embedded portion 1242 in the second opening 1232, as viewed in the vertical section passing through a center axis of the electrode 1240. In the element mounting board 1200 according to the present embodiment, a peripheral edge of the second opening 1232 lies external to a peripheral edge of the first opening 1032. In other words, the width d of the second opening 1232 is greater than the width c of the first insulating layer 1030, as viewed in the vertical section passing through a center axis of the electrode 1240. Though the thickness of the gold plating layer 1245 is not taken into account here, the same structure and operation work even if the thickness of the gold plating layer 1245 is taken into consideration instead.

The semiconductor element 1300 is mounted on the element mounting board 1200 having the above-described structure, thereby forming the semiconductor module 1002. More specifically, the semiconductor element 1300 is flip-chip connected to the element mounting board 1100 in such a manner that the element electrodes and the protrusions 1244 of the electrodes 1240 are bonded together by the solder balls 1080.

Method for Fabricating an Element Mounting Board and a Semiconductor Module

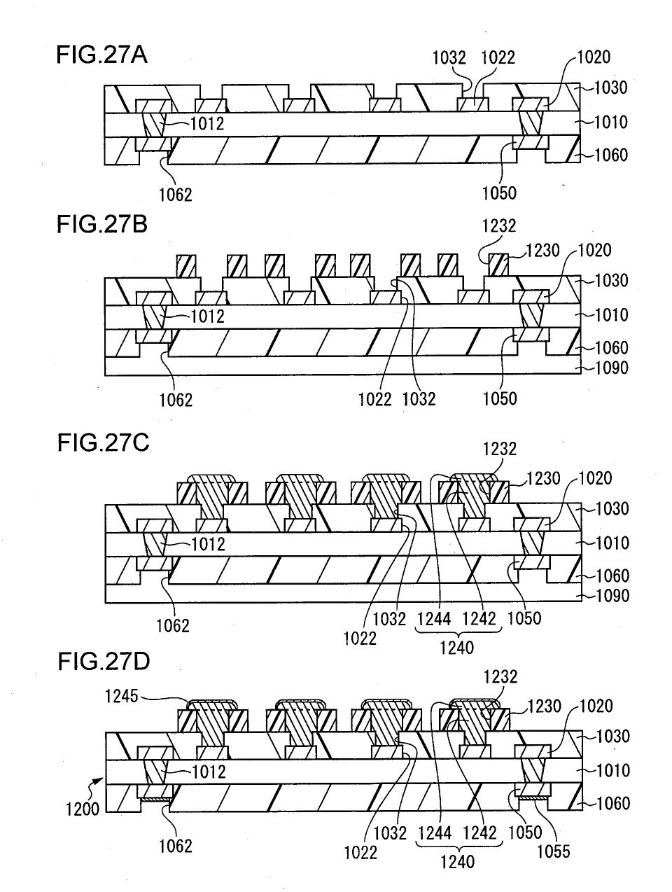

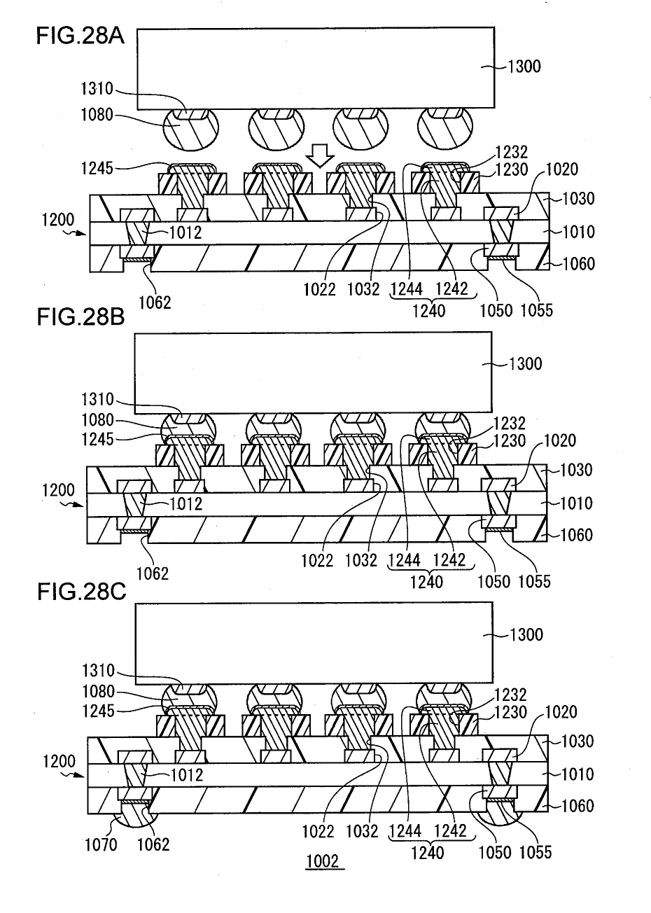

A method for manufacturing a semiconductor module 1002 according to the thirteenth embodiment is described with reference to FIG. 27A to FIG. 28C. FIGS. 27A to 27D and FIGS. 28A to 28C are cross-sectional views showing processes in the method for fabricating the semiconductor module 1002.

As shown in FIG. 27A, a photo solder resist is first laminated on one main surface of the substrate 1010 in which the wiring layers 1020 and the like have been formed through the process of FIGS. 21A to 21D. Then, the first insulating layer 1030 having the first openings 1032 in which the electrode forming regions 1022 of the wiring layer 1020 are exposed are formed, using a known photolithography method. Similar to the one main surface thereof, a photo solder resist is laminated on the other main surface of the substrate 1010 and then the lower-surface-side insulating layer 1060 having the lower-surface-side openings 1062 in which the land areas of the lower-surface-side wiring layers 1050 are exposed in predetermined regions are formed, using a known photolithography method.

Then, as shown in FIG. 27B, a photo solder resist is laminated on one main surface of the first insulating layer 1030 opposite to the substrate 1010 and then the second insulating layer 1230 having the second openings 1232 in which the electrode forming regions 1022 are exposed are formed, using a known photolithography method. A mask 1090 is laminated on one main surface of the lower-surface-side insulating layer 1060 opposite to the substrate 1010 in such a manner as to cover this opposite-side main surface thereof in its entirety.

Then, as shown in FIG. 27C, copper is filled above the electrode forming regions 1022, using the electrolytic plating method. In this plating process, copper is first gradually filled into the first openings 1032 provided in the first insulating layers 1030 and then the first openings 1032 are completely filled with copper. Furthermore, the copper starts to spread over a top surface of the first insulating layer 1030 and then blocked by the second insulating layer 1230. Then the copper is gradually built up by the plating, and the second opening 1232 is completely filled with copper, thereby forming the embedded portion 1242. After this, the copper is further built up by the plating and therefore the copper protrudes above the upper surface of a periphery of the second opening 1232 of the second insulating layer 1230. At the same time, the peripheral edge of copper spreads toward a region external to the second opening 1232, as viewed from above the second insulting layer 1230. This process results in the formation of the protrusion 1244. The size of the protrusion 1244 may be adjusted, as appropriate, by adjusting the plating processing time.

Then, as shown in FIG. 27D, the plating mask 1090 is removed using a remover. Then, by using the electrolytic plating method, a gold plating layer 1245 is formed on a surface of the protrusion 1244, and a gold plating layer 1055 is formed in the land area of the lower-surface-side wiring layer 1050. An element mounting board 1200 according to the thirteenth embodiment is manufactured through the above-described processes.

Then, as shown in FIG. 28A, a semiconductor element 1300 is prepared where stud bumps 1310 are provided in element electrodes and solder balls 1080 are mounted on the stud bumps 1310. Then the semiconductor element 1300 is mounted on the element mounting board 1200.

Then, as shown in FIG. 28B, a reflow process is performed with the semiconductor element 1300 mounted on the element mounting board 1200. That is, in this reflow process, the solder balls 1080 are joined to the protrusions 1244 and thereby the electrodes 1240 and the element electrodes are electrically coupled to each other.

Then, as shown in FIG. 28C, the solder balls 1070 are mounted on the lower-surface-side wiring layers 1050, in the lower-surface-side openings 1062 provided in the lower-surface-side insulating layer 1060.

A semiconductor module 1002 according to the thirteenth embodiment is manufactured through the above-described processes. Though not shown in the Figures, an underfill material may be filled into a gap between the semiconductor element 1300 and the element mounting board 1200. Also, a sealing resin layer may seal the semiconductor element 1300 by using the transfer mold method.

To sum up the operations of and the advantageous effects achieved by the arrangement thus far explained, the following advantageous effect is achieved in addition to the above-described effects achieved by the twelfth embodiment. That is, in the element mounting board 1200 according to the thirteenth embodiment, the peripheral edge of the second opening 1232 lies external to the peripheral edge of the first opening 1032, as viewed from above the second insulating layer 1230. Thus, the size of flat part on top of the protrusion 1244 can be further increased, so that connection reliability between the element mounting board 1200 and the semiconductor element 1300 can be further improved.

If the distance between the semiconductor element and the element mounting board is set equal in both the conventional structure and the structure according to the thirteenth embodiment, the distance between the electrode 1240 and the semiconductor element 1300 in the thirteenth embodiment is much shorter than that in the conventional structure. This is because the protrusion 1244 of the electrode 1240 protrudes above the upper surface of the second insulating layer 1230 in the semiconductor module 1002 according to the thirteenth embodiment. As a result, the diameter of the solder ball 1070 can be made smaller and thus the pitch between the electrodes 1240 can be further reduced. Hence, the size of the semiconductor module 1002 can be further reduced.

### Fourteenth Embodiment

Next, a description will be given of a mobile apparatus (portable device) provided with a semiconductor device according to each of the above-described embodiments. The mobile apparatus presented as an example herein is a mobile phone, but it may be any electronic apparatus, such as a personal digital assistant (PDA), a digital video cameras (DVC) or a digital still camera (DSC).

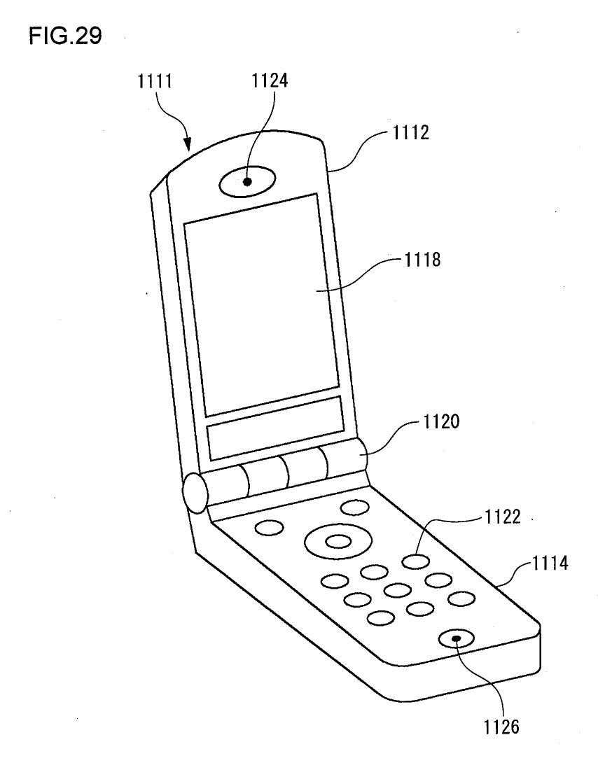

FIG. 29 illustrates a structure of a mobile phone incorporating a semiconductor device 10 or semiconductor modules 1001 and 1002 according to the above-described embodiments of the present invention. A mobile phone 1111 is structured such that a first casing 1112 and a second casing 1114 are jointed together by a movable part 1120. The first casing 1112 and the second casing 1114 are turnable around the movable part 1120 as the axis. The first casing 1112 is provided with a display unit 1118 for displaying characters, images and other information and a speaker unit 1124. The second casing 1114 is provided with a control module 1122 with operation buttons and the like and a microphone 1126. Note that the semiconductor device 10, 1001 or 1002 according to each of the embodiments of the present invention is mounted within a mobile phone 1111 such as this.

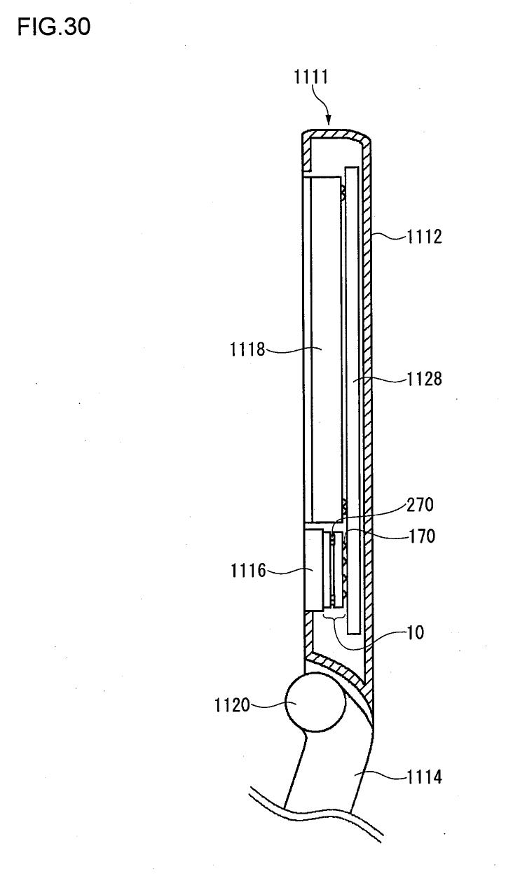

FIG. 30 is a partial cross-sectional view (cross-sectional view of the first casing 1112) of the mobile phone (incorporating the semiconductor device 10) shown in FIG. 29. A semiconductor device 10 according to the present embodiment is mounted on a printed circuit board 1128 via solder bumps 170 and is coupled electrically to the display unit 1118 and the like by way of the printed circuit board 1128. Also, a radiating substrate 1116, which may be a metallic substrate or the like, is provided on the back side of the semiconductor device 10 (opposite side of the solder balls 170), so that the heat generated from the semiconductor device 10, for example, can be efficiently released outside the first casing 1112 without getting trapped therein.

By employing the semiconductor device 10 according to each of the above-described embodiments, the packaging area of the semiconductor device 10 can be reduced. Thus, a portable device, provided with such a semiconductor device 10, according to the present embodiment can be made smaller and thinner.

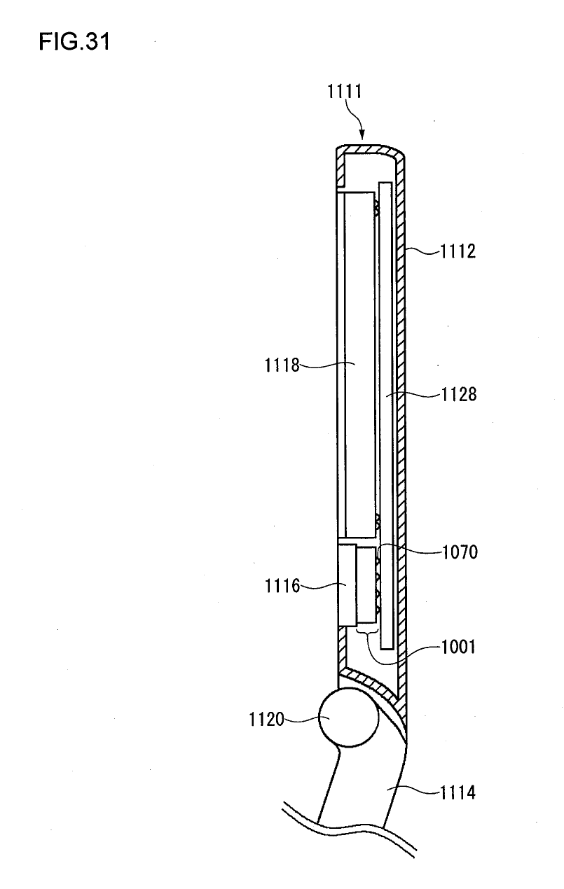

FIG. 31 is a partial cross-sectional view (cross-sectional view of the first casing 1112) of the mobile phone (incorporating the semiconductor module 1001) shown in FIG. 29. The semiconductor module 1001 is mounted on a printed circuit board 1128 via solder balls 1070 and is coupled electrically to the display unit 1118 and the like by way of the printed circuit board 1128. Also, a radiating substrate 1116, which may be a metallic substrate or the like, is provided on the back side of the semiconductor module 1001 (opposite side of the solder balls 1070), so that the heat generated from the semiconductor device 10, for example, can be efficiently released outside the first casing 1112 without getting trapped therein. Note that FIG. 31 illustrates a case where the semiconductor module 10 according to the twelfth embodiment is mounted but the mobile phone may incorporate the semiconductor module 1002 according to the thirteenth embodiment.

By employing the semiconductor modules 1001 and 1002 according to each of the above-described embodiments, the connection reliability between the element mounting boards 110 and 1200 and the semiconductor element 1300 can be improved. Thus, the reliability of a portable device, provided with such semiconductor modules 1001 and 1002, according to the present embodiment improves.

The present invention is not limited to the above-described embodiments, and it is understood by those skilled in the art that various modifications such as changes in design may be made based on their knowledge and the embodiments added with such modifications are also within the scope of the present invention.

In the first embodiment, for example, a single semiconductor element 220 is mounted in the second semiconductor module 200. The second semiconductor module 200 may be a stack type multi-chip package where a plurality of semiconductor elements are stacked together similarly to the first semiconductor module 100 and each of the semiconductor elements is connected by the wiring bonding. According to this modification, the same advantageous effects as those of the fifth embodiment can be achieved.

In the semiconductor device according to the eleventh embodiment, the semiconductor element 120 and the semiconductor element 220 are connected by the wire bonding. In a modification, either one of or both of the semiconductor element 120 and the semiconductor element 220 may be flip-chip connected.

The electrodes 1040 and 1240 in the above-described twelfth and thirteenth embodiments, are flip-chip connected to the electrodes of the semiconductor element 1300. In a modification, the electrodes 1040 and 1240 may be used as land areas for the wiring-bonding connection.

### DESCRIPTION OF THE REFERENCE NUMERALS

10 Semiconductor device
100 First semiconductor module
130 Insulating resin layer
140, 142 Third electrode portions
150 First insulating layer
152 Second insulating layer
200 Second semiconductor module
1001, 1002 Semiconductor modules
1010 Substrate (base material)
1011 Via hole
1012 Via conductor
1020 Wiring layer
1021 Copper foil
1022 Electrode forming region
1030 First insulating layer
1032 First opening
1040, 1240 Electrodes
1042, 1024 Embedded portions
1044, 1244 Protrusions
1045, 1055, 1245 Gold plating layer
1050 Lower-surface-side wiring layer
1051 Copper foil
1060 Lower-surface-side insulating layer
1062 Lower-surface-side opening
1070, 1080 Solder balls
1090 Plating mask
1100, 1200 Device mounting boards
1230 Second insulating layer
1232 Second opening
1300 Semiconductor device
1310 Stud bump

### INDUSTRIAL APPLICABILITY

The present invention reduces the area required by the solder balls and the electrode pads for a package and the mounting of a semiconductor element, thereby attaining further miniaturization and higher density of the semiconductor device.

1. An element mounting board used to mount a semiconductor element thereon, the element mounting board comprising:
a substrate;
a wiring layer formed on one main surface of said substrate;
an electrode portion, provided on the one main surface of said substrate, said electrode portion being thicker than the thickness of said wiring layer, and said electrode portion being used for solder bonding.

2. An element mounting board according to claim 1, wherein said element mounting board is used for a semiconductor device having a package-on-package structure.

3. An element mounting board according to claim 1, further comprising:
a first conductor provided on the main surface of said substrate, the first conductor belonging to the same layer to which said wiring layer belongs;
a first insulating layer having a first opening in which said first conductor is exposed;
a second insulating layer provided on said first insulating layer, said second insulating having a second opening in which an upper surface of said first insulating layer in a peripheral edge of the first opening is exposed; and
a second conductor filled into the first opening and a part of the second opening,
wherein said electrode portion includes said first conductor and said second conductor.

4. A semiconductor module, comprising:
an element mounting board according to claim 1;
a semiconductor element mounted at one main surface side of the substrate; and
a sealing resin for sealing said semiconductor element.

5. A semiconductor module, comprising:
an element mounting board according to claim 2;
a semiconductor element mounted at the other main surface side of the substrate; and
a sealing resin for sealing said semiconductor element.

6. A semiconductor device, comprising:
a first semiconductor module including:
a substrate;
a first semiconductor element mounted at one main surface side of the substrate;
a sealing resin for sealing the first semiconductor element;
a wiring layer formed on one main surface of the substrate; and
a first electrode portion provided on the main surface of the substrate, the first electrode portion having an upper surface, used for solder bonding, which is positioned above an upper surface of the wiring layer;
a second semiconductor module, mounted above the sealing resin, having a second electrode portion on a lower surface thereof, wherein a second semiconductor element is packaged in said second semiconductor module; and
a solder member for connecting the first electrode portion to the second electrode portion.

7. A semiconductor device according to claim 6, further comprising:
a first conductor provided on the main surface of the substrate, said first conductor belonging to the same layer to which the wiring layer belongs;
a first insulating layer having a first opening in which said first conductor is exposed;
a second insulating layer provided on said first insulating layer, said second insulating having a second opening in which an upper surface of said first insulating layer in a peripheral edge of the first opening is exposed; and
a second conductor filled into the first opening and a part of the second opening,
wherein the first electrode portion includes said first conductor and said second conductor.

8. A semiconductor device, comprising:
a first semiconductor module including:
a substrate;
a first semiconductor element mounted at one main surface side of the substrate;
a sealing resin for sealing the first semiconductor element;
a first wiring layer formed on one main surface of the substrate; and
a first electrode portion provided on the main surface of the substrate, the first electrode portion having an upper surface used for solder bonding;
a second semiconductor module, mounted above the sealing resin, having a second electrode portion and a second wiring layer on a lower surface thereof; and
a solder member for connecting the first electrode portion to the second electrode portion,
wherein the thickness of the second electrode portion is greater than that of the second wiring layer.

9. A semiconductor device according to claim 8, further comprising:
a first conductor provided at a lower surface side of said second semiconductor module, said first conductor belonging to the same layer to which the second wiring layer belongs;
a first insulating layer having a first opening in which said first conductor is exposed;
a second insulating layer provided on said first insulating layer, said second insulating having a second opening in which a top surface of said first insulating layer in a peripheral edge of the first opening is exposed; and
a second conductor filled into the first opening and a part of the second opening,
wherein the second electrode portion includes said first conductor and said second conductor.

10. A method for fabricating an element mounting board, the method comprising:
a process of patterning a wiring layer on one main surface of a substrate;
a process of forming a first insulating layer having an opening in which an electrode region is exposed, the electrode region being designed to bond a solder member used to mount a package; and
a process of filling a conductive material into the opening.

11. A method, for fabricating an element mounting board, according to claim 10, further comprising a process of forming a second insulating layer having an opening in which an upper surface of the first insulating layer in a peripheral edge of the opening is exposed,
wherein the opening in the first insulating layer is completely filled with the conductive material, and then the conductive material is filled so as to reach a side wall of the second insulating layer.

12. A method for fabricating a semiconductor device, the method comprising:
a process of preparing a first semiconductor module including a first substrate and a first semiconductor element mounted on the first substrate, wherein the first substrate is such that a wiring layer and a first electrode portion, whose thickness is greater than that of the wiring layer, used for solder bonding are formed in a semiconductor element mounting surface;
a process of preparing a second semiconductor module including a second substrate and a second semiconductor element mounted on the second substrate, wherein the second substrate is such that a second electrode portion used for solder bonding is formed in an opposite side of the semiconductor element mounting surface; and
a process of joining together said first semiconductor module and said second semiconductor module by placing said second semiconductor module on top of said first semiconductor module.

13. (canceled)

14. An element mounting board, comprising:
a substrate;
a wiring layer, formed on one main surface of said substrate, having an electrode forming region;
an insulating layer, provided on a periphery of the electrode forming region, having an opening in which the electrode forming region is exposed; and
an electrode electrically connected to the electrode forming region, said electrode having an embedded portion embedded into the opening of said insulating layer and a protrusion protruding above an upper surface of a periphery of the opening of said insulating layer,
wherein an peripheral edge of the protrusion lies external to an peripheral edge of the embedded portion, as viewed from above said electrode.

15. An element mounting board according to claim 14, wherein a periphery of a flat part in an upper surface of the protrusion lies external to the peripheral edge of the embedded portion, as viewed from above said electrode.

16. An element mounting board according to claim 14,
wherein said insulating layer serves as a first insulating layer and the opening serves as a first opening,
wherein said element mounting board further comprises a second insulating layer, provided on a periphery of the first opening on said first insulating layer, said second insulating layer having a second opening in which the electrode forming region is exposed, and
wherein said electrode is such that the embedded portion is embedded into the first opening and the second opening,
the protrusion protrudes above an upper surface of a periphery of the second opening of said second insulating layer, and
the peripheral edge of the protrusion lies external to that of the embedded portion, as viewed from above said electrode.

17. An element mounting board according to claim 16, wherein a periphery of a flat part in an upper surface of the protrusion lies external to the peripheral edge of the embedded portion, as viewed from above said electrode.

18. An element mounting board according to claim 16, wherein the periphery of the second opening lies external to that of the first opening, as viewed from above said second insulating layer.

19. (canceled)

20. (canceled)

21. (canceled)

22. (canceled)
